(19) United States
(12) Patent Application Publication
(10) Pub. No.: US 2023/0413542 A1
(43) Pub. Date: Dec. 21, 2023

(54) THREE-DIMENSIONAL MEMORY DEVICE HAVING STAIRCASE STRUCTURE AND METHOD FOR FORMING THE SAME

(71) Applicant: YANGTZE MEMORY TECHNOLOGIES CO., LTD., Wuhan (CN)

(72) Inventors: Ling Xu, Wuhan (CN); Zhong Zhang, Wuhan (CN); Wenxi Zhou, Wuhan (CN); Di Wang, Wuhan (CN); Zhiliang Xia, Wuhan (CN); Zongliang Huo, Wuhan (CN)

(21) Appl. No.: 17/843,674

(22) Filed: Jun. 17, 2022

(51) Int. Cl. H01L 27/11556; H01L 27/11521

(52) U.S. Cl. CPC H01L 27/11556; H01L 27/11521

(57) ABSTRACT

A three-dimensional (3D) memory device includes interleaved conductive layers and dielectric layers. Edges of the conductive layers and dielectric layers define a plurality of stairs. The 3D memory device also includes a plurality of landing structures each over a respective conductive layer at a respective stair. Each of the landing structures includes a first layer having a first material and a second layer having a second material, the first layer being over the second layer.

### BACKGROUND

The present disclosure relates to memory devices and methods for forming memory devices, and more particularly, to three-dimensional (3D) memory devices and methods for forming 3D memory devices.

Planar semiconductor devices, such as memory cells, are scaled to smaller sizes by improving process technology, circuit design, programming algorithm, and fabrication process. However, as feature sizes of the semiconductor devices approach a lower limit, planar process and fabrication techniques become challenging and costly. A 3D semiconductor device architecture can address the density limitation in some planar semiconductor devices, for example, Flash memory devices.

### SUMMARY

In one aspect, a 3D memory device includes interleaved conductive layers and dielectric layers. Edges of the conductive layers and dielectric layers define a plurality of stairs. The 3D memory device also includes a plurality of landing structures each over a respective conductive layer at a respective stair. Each of the landing structures includes a first layer having a first material and a second layer having a second material, the first layer being over the second layer.

In some implementations, the second layer is between the first layer and the respective conductive layer.

In some implementations, the first material includes a conductive material, and the second material includes a dielectric material.

In some implementations, the first material includes tungsten.

In some implementations, the second material includes silicon oxide, silicon oxynitride, or a combination thereof.

In some implementations, at each of the plurality of stairs, a respective dielectric layer is above and in contact with a respective conductive layer.

In some implementations, the 3D memory device includes a cover dielectric layer, the cover dielectric layer comprising a plurality of portions over the plurality of stairs. At the each of the plurality of stairs, a respective portion of the cover dielectric layer is in contact with the respective dielectric layer and the respective conductive layer; and the second layer includes the portion of the cover dielectric layer and a portion of the respective dielectric layer.

In some implementations, the first material includes tungsten, and the second material includes silicon oxide.

In some implementations, a thickness of the first layer is less than or equal to 55 nm.

In some implementations, the landing structure further includes a third layer having a third material, the third layer in the first layer and being different from the first material.

In some implementations, the third material is fully surrounded by the first layer.

In some implementations, the third material includes silicon oxide, silicon nitride, silicon oxynitride, polysilicon, carbon, or a combination thereof.

In some implementations, the third material includes airgap.

In some implementations, a total thickness of the first layer and the respective conductive layer is greater than or equal to 55 nm.

In some implementations, the 3D memory device further includes a plurality of interconnect structures each penetrates the first layer and the second layer. The interconnect structures are each in contact with the respective conductive layer.

In some implementations, the 3D memory device further includes a channel structure in the interleaved conductive layers and dielectric layers. The channel structure includes a high-k dielectric layer, a memory film, and a semiconductor layer.

In some implementations, the 3D memory device further includes a plurality of support structures extending in the interleaved conductive layers and dielectric layers.

In another aspect, a memory system includes a 3D memory device. The 3D memory device includes interleaved conductive layers and dielectric layers. Edges of the conductive layers and dielectric layers define a plurality of stairs. The 3D memory device also includes a plurality of landing structures each over a respective conductive layer at a respective stair. Each of the landing structures includes a first layer having a first material and a second layer having a second material, the first layer being over the second layer. The memory system also includes a memory controller coupled to the 3D memory device and configured to control operations of the 3D memory device.

In some implementations, the second layer is between the first layer and the respective conductive layer.

In some implementations, the first material includes a conductive material, and the second material includes a dielectric material.

In some implementations, the first material includes tungsten, and the second material includes silicon oxide, silicon oxynitride, or a combination thereof.

In some implementations, the memory system includes a cover dielectric layer, the cover dielectric layer having a plurality of portions over the plurality of stairs. At each of the plurality of stairs, a respective dielectric layer is above and in contact with a respective conductive layer; a respective portion of the cover dielectric layer is in contact with the respective dielectric layer and the respective conductive layer; and the second layer includes the portion of the cover dielectric layer and a portion of the respective dielectric layer.

In some implementations, the first material includes tungsten, and the second material includes silicon oxide; and a thickness of the first layer is less than or equal to 55 nm.

In some implementations, the landing structure further includes a third layer having a third material, the third material in the first layer and being different from the first material.

In some implementations, the third material includes silicon oxide, silicon nitride, silicon oxynitride, polysilicon, carbon, or a combination thereof.

In some implementations, the third material includes airgap.

In some implementations, a total thickness of the first layer and the respective conductive layer is greater than or equal to 55 nm.

In another aspect, a method for forming a 3D memory device includes forming a stack structure comprising interleaved sacrificial layers and dielectric layers, edges of the dielectric layers and the sacrificial layers defining a plurality of stairs; forming sacrificial portions each on a respective stair; forming a plurality of interconnect structures each penetrating the respective sacrificial portion and in contact with a respective sacrificial layer of the respective stair; removing the sacrificial portions and the sacrificial layers to form a plurality of lateral recesses; and depositing a conductive material into the lateral recesses.

In some implementations, the lateral recesses each comprising a first recess portion and a second recess portion over the first recess portion; and depositing the conductive material into the lateral recesses includes filling the first recess portion and filling at least part of the second recess portion of each of the lateral recesses.

In some implementations, depositing the conductive material includes fully filling the first recess portion of each of the lateral recesses.

In some implementations, depositing the conductive material includes fully filling the second recess portion of each of the lateral recesses.

In some implementations, depositing the conductive material includes partially filling the second recess portion of each of the lateral recesses.

In some implementations, depositing the conductive material includes depositing tungsten, aluminum, cobalt, copper, polysilicon, or a combination thereof.

In some implementations, the method further includes depositing a second material different from the conductive material to fill the second recess portion.

In some implementations, the method further includes removing the conductive material in the second recess portion prior to the deposition of the second material.

In some implementations, depositing the second material includes depositing silicon oxide, silicon nitride, silicon oxynitride, polysilicon, carbon, or a combination thereof.

In some implementations, the method further includes forming a cover dielectric layer over the dielectric layers. Forming the sacrificial portions includes forming a sacrificial material layer over the cover dielectric layer; and removing portions of the sacrificial material layer to form the sacrificial portions each being disconnected from one another.

In some implementations, the cover dielectric layer includes silicon oxide and forming the cover dielectric layer includes an atomic layer deposition.

In some implementations, forming the sacrificial portions includes etching the dielectric layers to expose the sacrificial layers each at a respective stair; forming a sacrificial material layer over the sacrificial layers; and removing portions of the sacrificial material layer to form the sacrificial portions each being disconnected from one another.

In some implementations, forming the plurality of interconnect structures each landed on a respective sacrificial layer of the respective stair includes forming the plurality of interconnect openings each in contact with a respective sacrificial portion of the respective stair; continuing to etch the interconnect openings such that the interconnect openings each being in contact with the respective sacrificial layer; and depositing a material of interconnect structures such that the interconnect structures each extends through the respective sacrificial portion and is landed on the respective sacrificial layer.

In some implementations, the method further includes forming a channel structure extending in the stack structure prior to a formation of the stairs. Forming the channel structure includes forming a channel hole extending in the stack structure; and depositing a high-k dielectric layer in the channel hole, a memory film over the high-k dielectric layer, and a semiconductor layer over the memory film.

In some implementations, the method further includes, after a formation of the interconnect structures, forming a slit structure in the interleaved sacrificial layers and dielectric layers; and performing an isotropic etching process to remove the sacrificial layers and the sacrificial portions to form the lateral recesses.

In some implementations, the method further includes forming a plurality of support structures extending in the stack structure prior to a formation of the slit structure.

In some implementations, the support structures are formed prior to a formation of the interconnect structures.

In some implementations, the support structures are formed after a formation of the interconnect structures.

### BRIEF DESCRIPTION OF THE DRAWINGS

The accompanying drawings, which are incorporated herein and form a part of the specification, illustrate aspects of the present disclosure and, together with the description, further serve to explain the present disclosure and to enable a person skilled in the pertinent art to make and use the present disclosure.

FIG. 1 illustrates a cross-section of a 3D memory device.

FIG. 2A illustrates a top view of an exemplary 3D memory device, according to some aspects of the present disclosure.

FIGS. 2B-2E each illustrates a cross-sectional view of an example of the 3D memory device in FIG. 2A, according to some aspects of the present disclosure.

FIGS. 3A-3I illustrate cross-sectional views of an exemplary 3D memory device at different stages of a fabrication process, according to some aspects of the present disclosure.

FIGS. 4A-4C illustrate cross-sectional views of an exemplary 3D memory device at different stages of another fabrication process, according to some aspects of the present disclosure.

FIGS. 5A-5E illustrate cross-sectional views of another exemplary 3D memory device at different stages of a fabrication process, according to some aspects of the present disclosure.

FIG. 6 illustrates a flowchart of an exemplary method for forming a 3D memory device, according to some aspects of the present disclosure.

FIG. 7 illustrates a flowchart of another exemplary method for forming another 3D memory device, according to some aspects of the present disclosure.

FIG. 8 illustrates a block diagram of an exemplary system having a memory device, according to some aspects of the present disclosure.

FIG. 9A illustrates a diagram of an exemplary memory card having a memory device, according to some aspects of the present disclosure.

FIG. 9B illustrates a diagram of an exemplary solid-state drive (SSD) having a memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which interconnect lines and/or via contacts are formed) and one or more dielectric layers.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “3D memory device” refers to a semiconductor device with vertically oriented strings of memory cell transistors (referred to herein as “memory strings,” such as NAND memory strings) on a laterally-oriented substrate so that the memory strings extend in the vertical direction with respect to the substrate. As used herein, the term “vertical/vertically” means nominally perpendicular to the lateral surface of a substrate.

In a 3D memory device, such as a 3D NAND memory device, a stack of interleaved conductive layers and dielectric layers (e.g., a memory stack) may be arranged over a substrate, and a plurality of channel structures extending through and intersecting with the conductive layers. The memory stack can be formed by replacing the sacrificial layers in a dielectric stack of interleaved sacrificial layers and dielectric layers with conductive layers in a gate replacement process. Memory cells are formed by the intersection between the conductive layers and the channel structures. Some of the conductive layers function as the word lines of the 3D NAND memory device, and are arranged in a plurality of stairs. Each of the stairs includes a top conductive layer having a landing area on which a word line contact is landed. The word line contact applies voltages on the top conductive layer for the operation of the 3D NAND memory device.

As the demand for higher capacity continues to increase, the number of conductive layers, e.g., word lines, increases in a 3D NAND memory device. The increase of the number of conductive layers results in an increase of the height of the stack, and the fabrication process to form the word line contacts becomes more challenging. For example, the word line contacts are formed by forming openings in a dielectric structure over the stairs and filling the openings with a conductive material. The openings, in contact with the top conductive layers of respective stairs, are often formed in the same patterning process. Due to the different elevations of the stairs, the etching can cause the top conductive layer in a higher stair to be over etched more, and that in a lower stair to be over etched less or even under etched. The over-etching of the top conductive layer can result in the opening being in contact with another conductive layer underlying the respective conductive layer, e.g., causing a “punch through” phenomenon. When the word line contacts are formed, the conductive material of the word line contacts may leak into the damaged underlying conductive layers, causing short circuits and/or leakage.

To reduce the possibility of damaging the top conductive layers, the landing area of a top conductive layer is thickened by forming an additional conductive portion. A word line contact is then formed to be landed on the conductive portion. To form a top conductive layer with a conductive portion, a sacrificial portion is formed in contact with a respective sacrificial layer in the landing area of the respective stair. In a gate replacement process, a gate-line slit is formed in the stack, the sacrificial portion and the sacrificial layer of a stair are then both removed through the gate-line slit to form a lateral recess, and a conductive material is deposited through the gate-line slit to fill in the lateral recess. The portion of the lateral recess at the landing area is thus thicker than the rest of the lateral recess. However, to form the sacrificial portion at each stair, a sacrificial material layer is often deposited and etched to form a plurality of sacrificial portions, each over a respective stair. The etching can be difficult to control, resulting in the sacrificial layers underlying the sacrificial portions to be susceptible to overetching. For example, the portion of a sacrificial layer at the landing area can be damaged or be disconnected from the rest of the sacrificial layer. A damaged sacrificial layer can cause the electrical connection between the respective word line contact and the rest of the conductive layer, when formed, to be disrupted.

Meanwhile, a 3D NAND memory device often includes a plurality of support pillars extending in the stack. The support pillars can provide support the stack in the fabrication process so that the stack is less susceptible to collapse. The support pillars are often made of a dielectric material. In a fabrication process, word line contacts are often formed after the support pillars. The formation of the word line contacts often includes etching of the dielectric material over the stack to form an opening and depositing a conductive material into the opening. To avoid being damaged by the etching process, the number and arrangement of support pillars in the stack can be limited. On the other hand, the alignment and etching to form the word line contacts require high precision, which can be difficult to achieve.

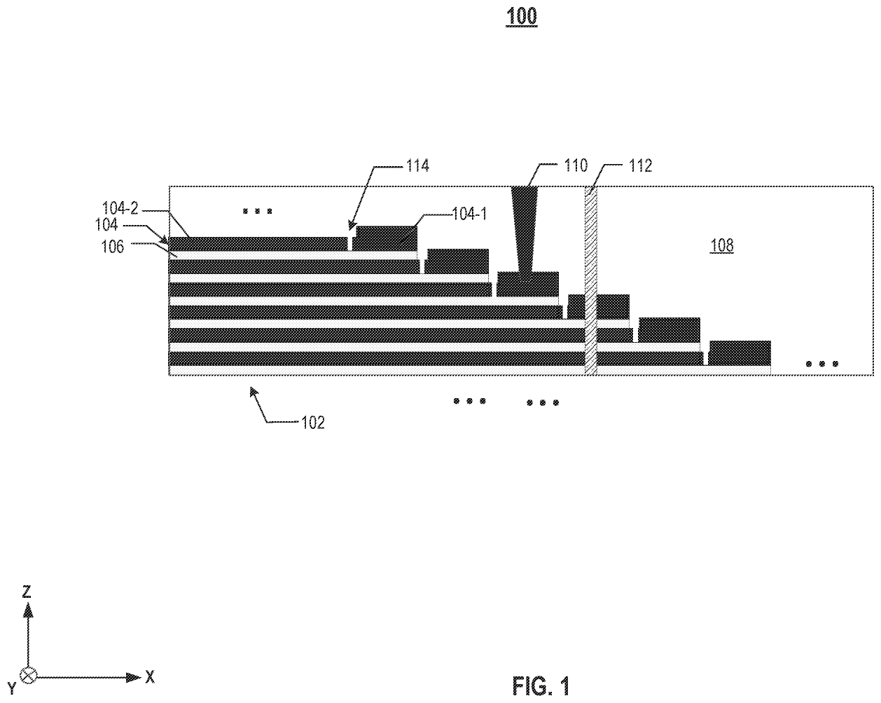

FIG. 1 illustrates a cross-sectional view of part of a 3D memory device 100 in which a top conductive layer is over etched at the landing area due to the reasons described above. 3D memory device 100 includes a stack structure 102 having interleaved a plurality of conductive layers 104 and dielectric layers 106 over a substrate (not shown). The edges of conductive layers 104 and dielectric layers 106 may define a plurality of stairs. Each of the stairs includes one of conductive layers 104 as the top conductive layer and an underlying dielectric layer 106. 3D memory device 100 also includes a dielectric structure 108 over the stairs and a plurality of word line contacts 110 in dielectric structure 108. Each word line contact 110 (e.g., an interconnect structure) is in contact with the landing area of a respective conductive layer 104 of a respective stair. A landing area of a stair may refer to the area used for the landing (e.g., contact or connection) of a word line contact 110, on the stair, as part or extension of conductive layer 104. For example, the landing area of a stair may be the area between the edges of an immediately upper stair and an immediately lower stair. 3D memory device 100 also includes a plurality of support pillars 112 extending in stack structure 102 and/or dielectric structure 108 into the substrate. The lateral distance (e.g., in the x-y plane) between word line contact 110 and support pillar 112 is sufficiently large to avoid contact. For ease of illustration, one word line contact 110 and one support pillar 112 are respectively shown.

As shown in FIG. 1, conductive layer 104 may include a first portion 104-1 and a second portion 104-2 in contact with each other. Conductive layer 104 includes a conductive material such as tungsten. First portion 104-1 represents the portion of conductive layer 104 at the landing area of the respective stair, and second portion 104-2 represents the rest of conductive layer 104. First portion 104-1 is formed by filling a recess structure, formed by the removal of a sacrificial portion and part of the underlying sacrificial layer, with the conductive material in a gate replacement process. To form the plurality of sacrificial portions, prior to the gate replacement process, a sacrificial material layer is deposited on the sacrificial layers of stack structure 102, the sacrificial material layer is etched to form the sacrificial portions, disconnected from each other. A portion of the sacrificial material layer, connecting sacrificial portions of adjacent stairs, can be removed. The sacrificial layers of stack structure 102 can be susceptible to over-etch by the etching process, and can be damaged after the portion is fully removed. For example, an opening 114 can be formed in the sacrificial layer, increasing the resistance in the subsequently-formed conductive layer. Sometimes, opening 114 can be undesirably deep such that the respective sacrificial portion is disconnected from the rest of the sacrificial layer. When conductive layers 104 and word line contacts 110 are formed, word line contacts 110 can be disconnected from second portion 104-2 of conductive layer 104. Thus, the electrical connection between word line contact 110 and conductive layer 104 can be disrupted, and the operation of the 3D NAND memory device can be impaired.

The present disclosure provides 3D memory devices and fabrication methods to form the 3D memory devices. The 3D memory device includes a memory stack that has a plurality of stairs extending on at least one side of a stack of interleaved conductive layers and dielectric layers (e.g., a memory stack). The 3D memory device includes a landing structure disposed on the respective conductive layer at the top surface of a respective stair. The landing structure has a first layer and a second layer. The first layer may be over the second layer. Word line contacts each penetrates the respective landing structure and is in contact with the respective conductive layer.

In some implementations, a 3D memory device includes a cover dielectric layer extending along the stairs, and each second layer includes a respective portion of the cover dielectric layer and a portion of the respective dielectric layer. The first material includes a conductive material, such as tungsten. In some implementations, the second material includes silicon oxide, silicon nitride, silicon oxynitride, or any combinations thereof. In some implementations, a 3D memory device includes a third layer of a third material partially or fully surrounded by the first layer. The third layer includes silicon oxide, silicon nitride, silicon oxynitride, polysilicon, carbon, airgap, or a combination thereof. In some implementations, the first material includes silicon oxide, silicon nitride, silicon oxynitride, polysilicon, carbon, or a combination thereof. The first layer (and the third layer, if any) is formed from a sacrificial portion disposed on the cover dielectric layer. The different choices of materials used to replace the sacrificial portion in the gate replacement process can be dependent on the thickness of the sacrificial portion. The thickness of the sacrificial portion is then less limited by the gate replacement process and other processes. In the meantime, the cover dielectric layer can reduce or prevent the over etch of the sacrificial materials during the formation of the sacrificial portions.

In some implementations, a 3D memory device does not include a cover dielectric layer. The first layer may cover or surround the second layer, partially or fully. The first material includes a conductive material, such as tungsten. In some implementations, the second material includes silicon oxide, silicon nitride, silicon oxynitride, polysilicon, carbon, airgap, or any combinations thereof. The first layer and the respective conductive layer are respectively formed from a sacrificial portion and a sacrificial layer. The formation of the sacrificial portion and the sacrificial layer, for each stair, allows a word line contact to stop at a desired depth. It may be easier to form an electrical connection between the word line contact and the subsequently-formed conductive layer. The landing window of the word line contact is improved. making.

In the present disclosure, 3D memory devices may include a plurality of support structures distributed amongst the word line contacts. The support structures can be formed before or after the formation of the word line contacts. For example, in some implementations, the support structures are formed after the formation of the word line contacts. It is thus easier to avoid contact between word line contacts and the support structures. In some implementations, more support structures can be formed in the 3D memory device, compared to another 3D memory device in which the support structures are formed before the formation of the word line contacts. In some implementations, slit structures, e.g., gate line slits (GLSs) are formed after the formation of the word line contacts and the support structures. In some implementations, forming the slit structures after the word line contacts and the support structures reduces the stress imposed in the 3D memory devices during the fabrication process.

In the present disclosure, the x-direction refers to the direction the word lines (i.e., conductive layers 104) extend, the y-direction refers to the direction the bit lines extend, the z-direction refers to the direction perpendicular to the x-y plane.

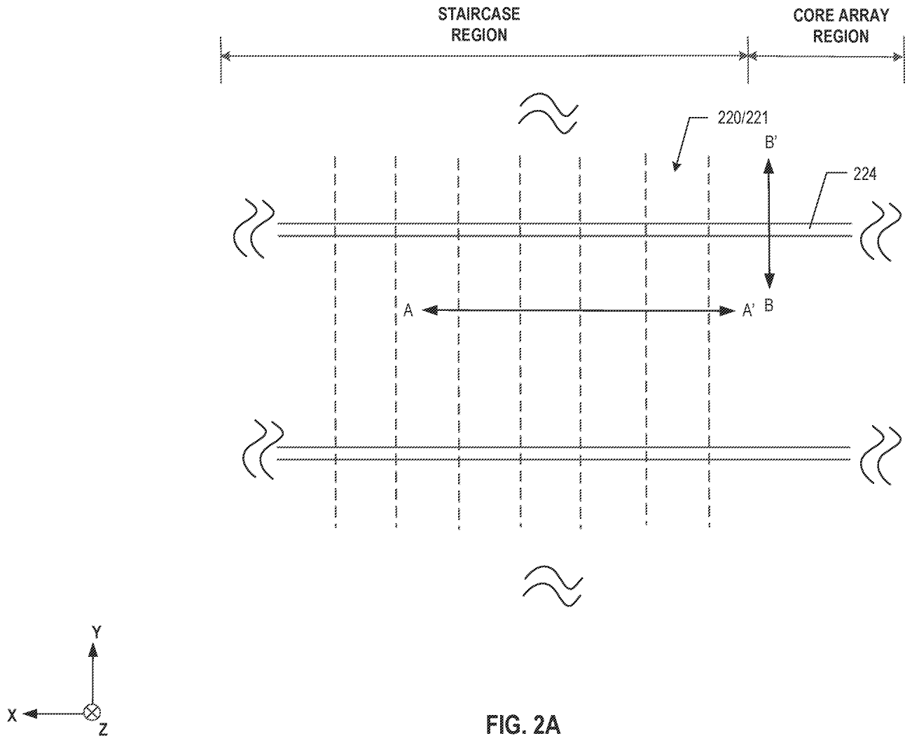

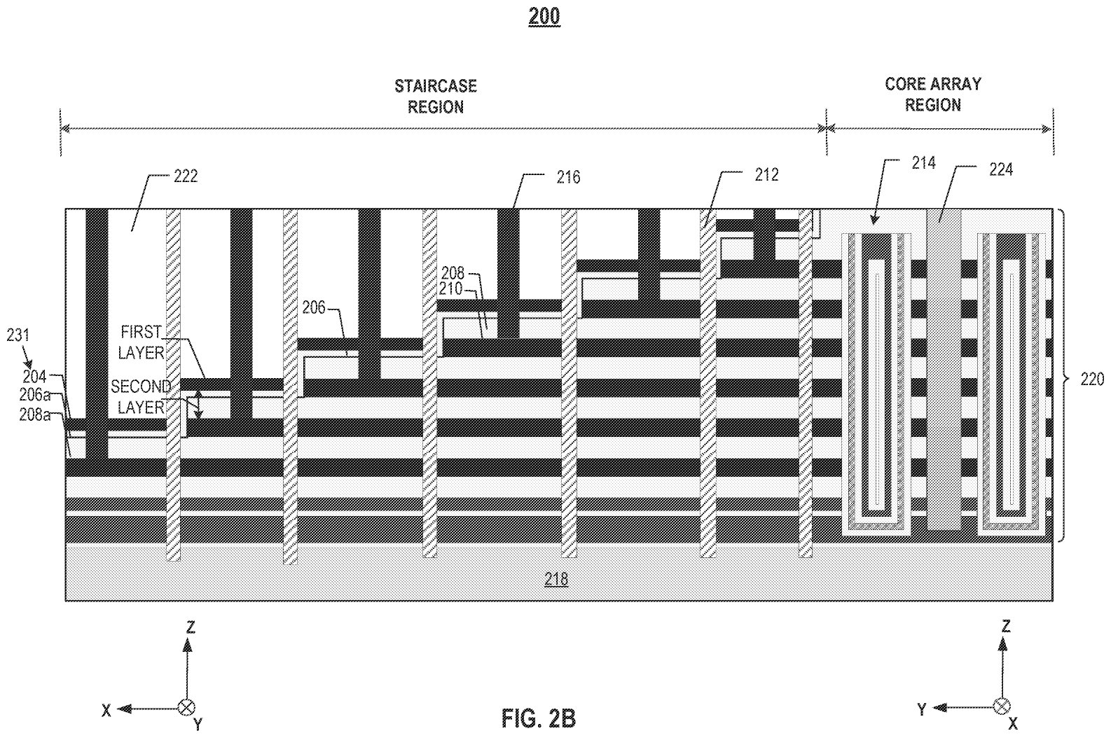

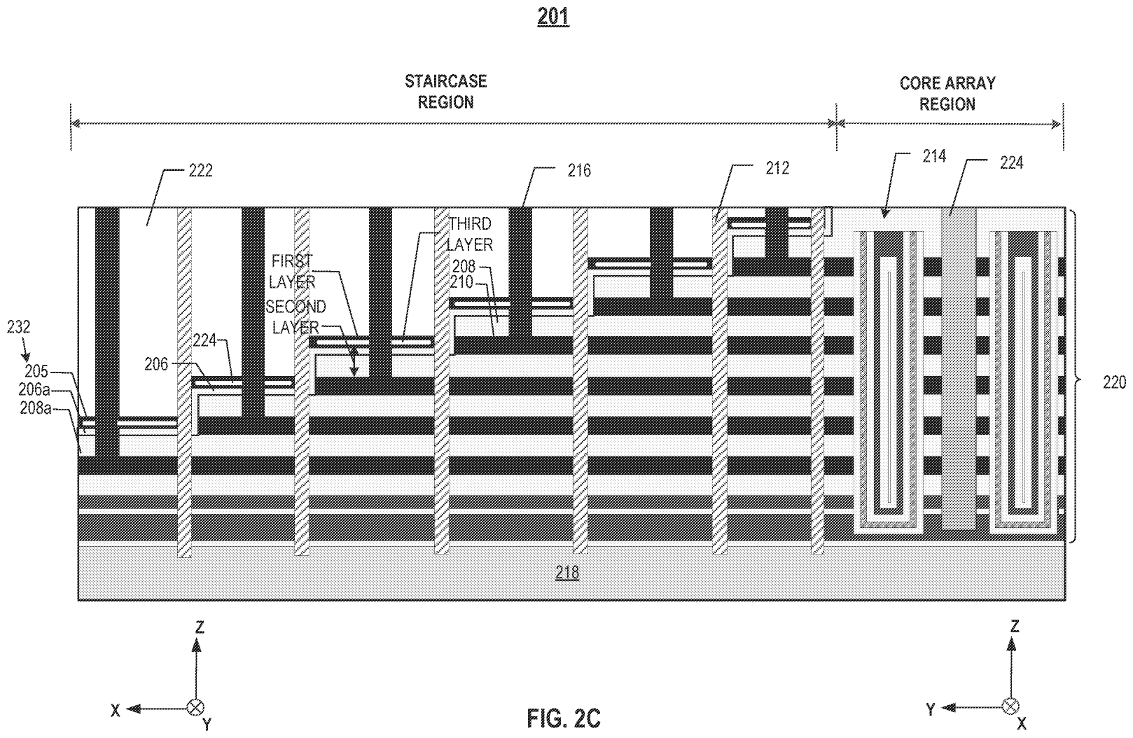

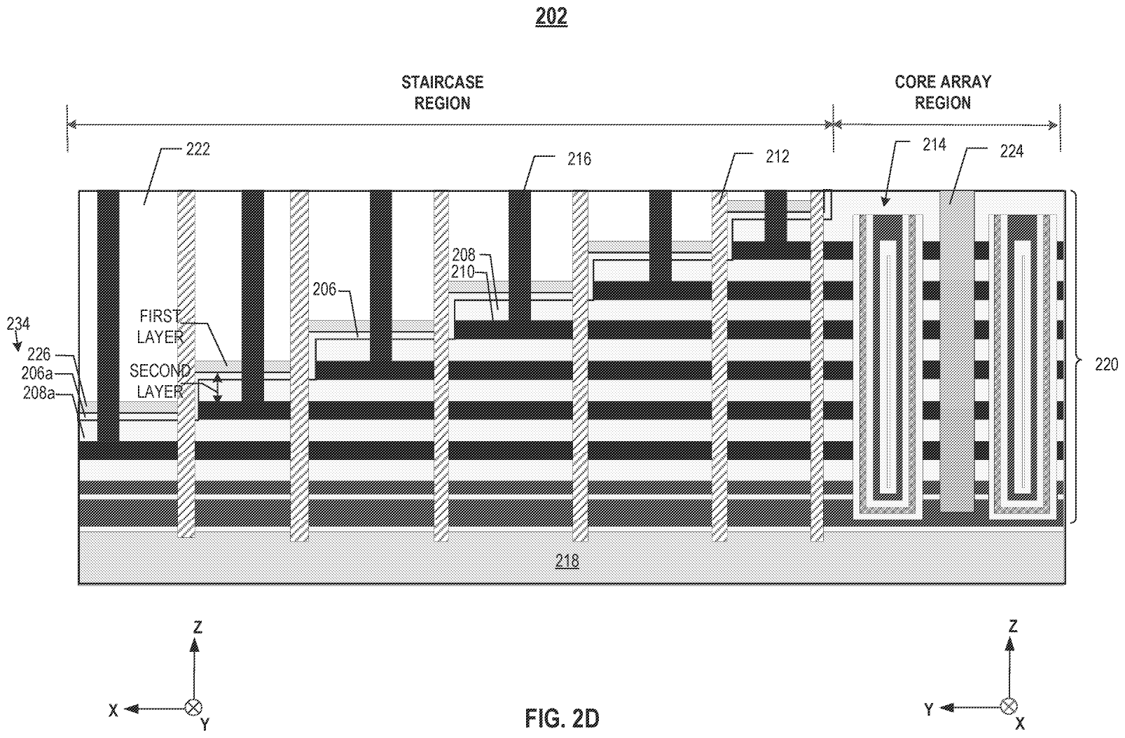

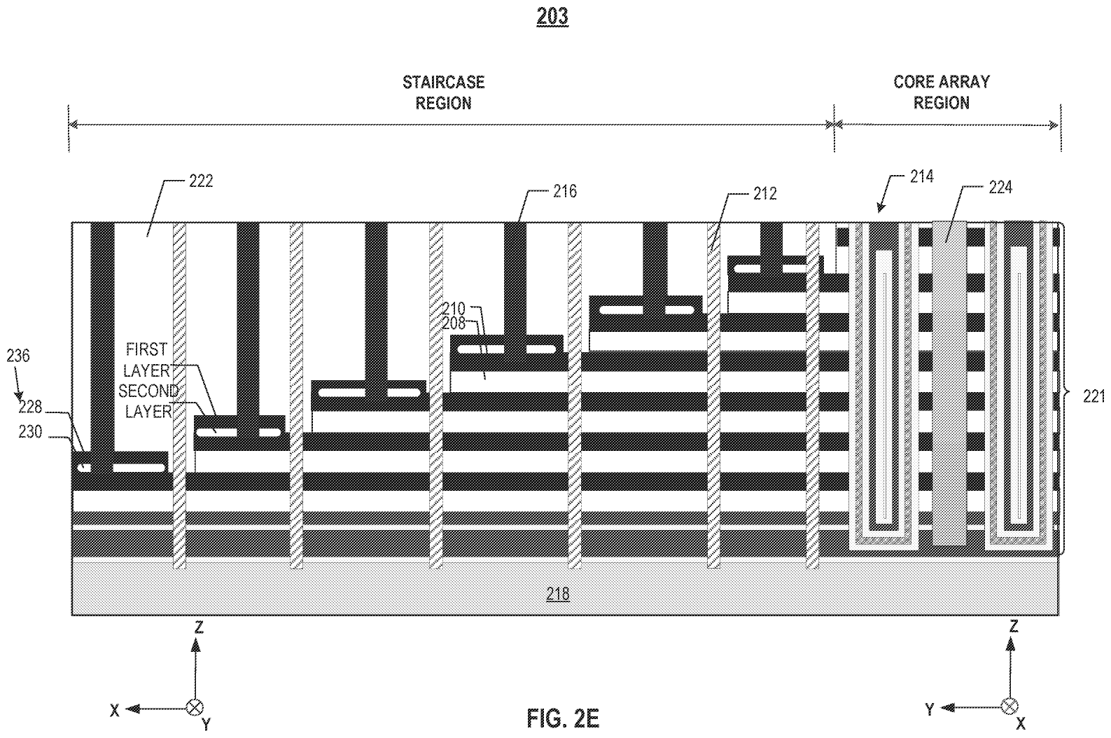

FIGS. 2A-2E illustrate part of 3D memory devices 200, 201, 202, and 203, according to some aspects of the present disclosure. 3D memory devices 200-203 may each be a 3D NAND memory device. FIG. 2A illustrates a top view of part of 3D memory devices 200-203. FIG. 2B illustrates a cross-sectional view of part of 3D memory device 200 in the A-A′ direction and B-B′ direction. FIG. 2C illustrates a cross-sectional view of part of 3D memory device 201 in the A-A′ direction and B-B′ direction. FIG. 2D illustrates a cross-sectional view of part of 3D memory device 202 in the A-A′ direction and B-B′ direction. FIG. 2E illustrates a cross-sectional view of part of 3D memory device 203 in the A-A′ direction and B-B′ direction. 3D memory devices 200, 201, 202, 203 may each include a core array region and a staircase region. A plurality of memory cells may be formed in the core array region for storing data, and a plurality of stairs may be formed in the staircase region for forming an electrical connection between word lines and peripheral circuits. As shown in FIGS. 2A-2E, cross-sections of part of the staircase regions along the A-A′ direction and cross-sections of part of the core array region along the B-B′ direction are shown for 3D memory devices 200, 201, 202, 203. For ease of illustration, similar or same parts in 3D memory devices 203 are described together.

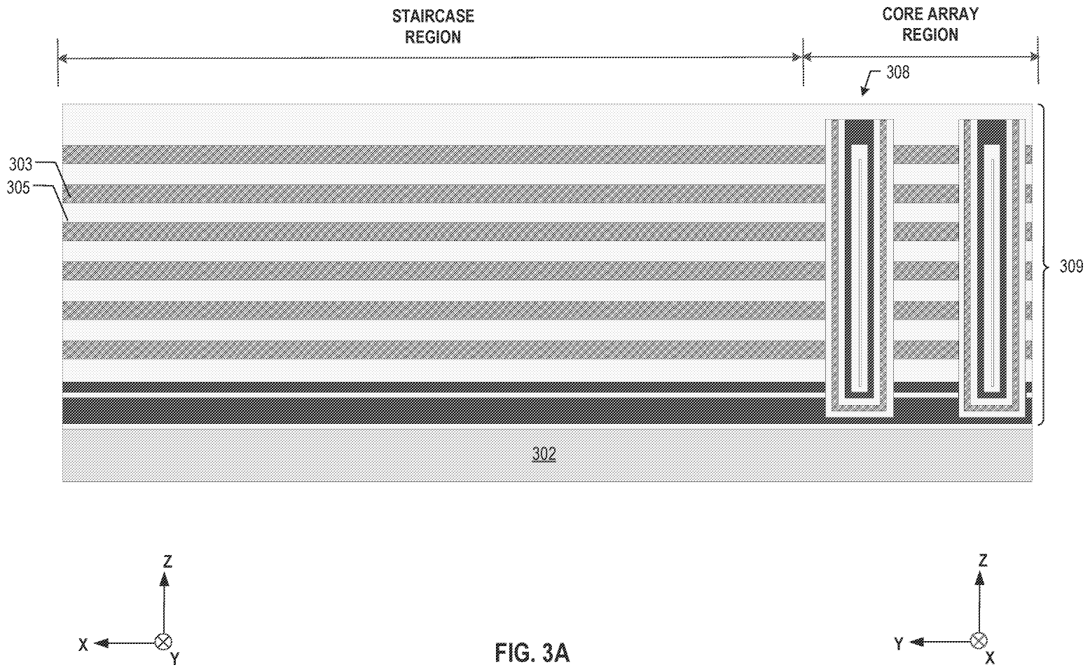

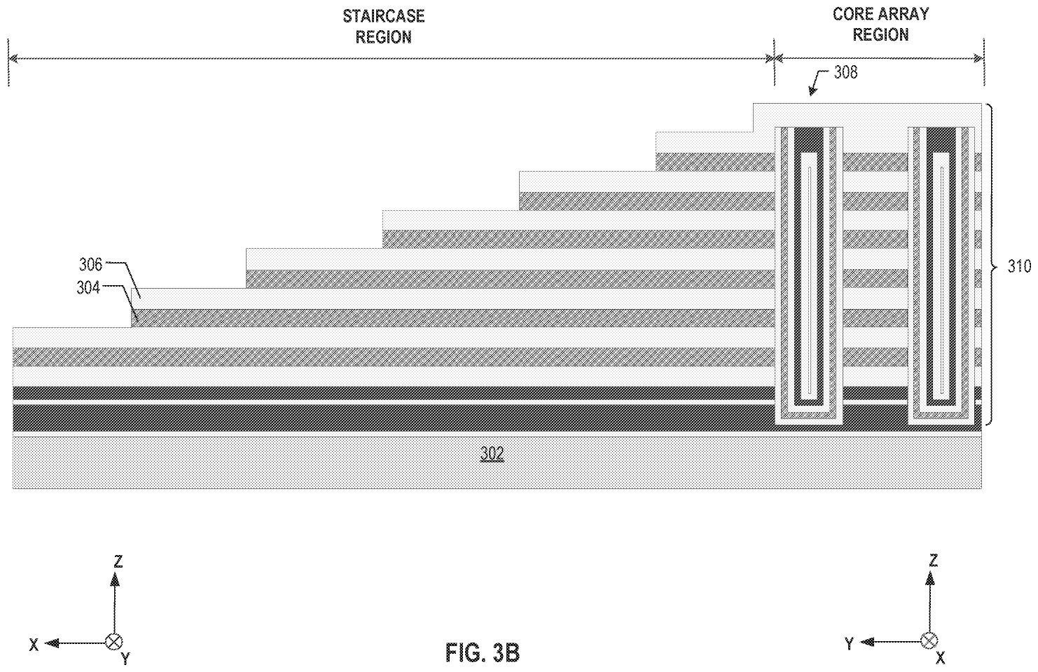

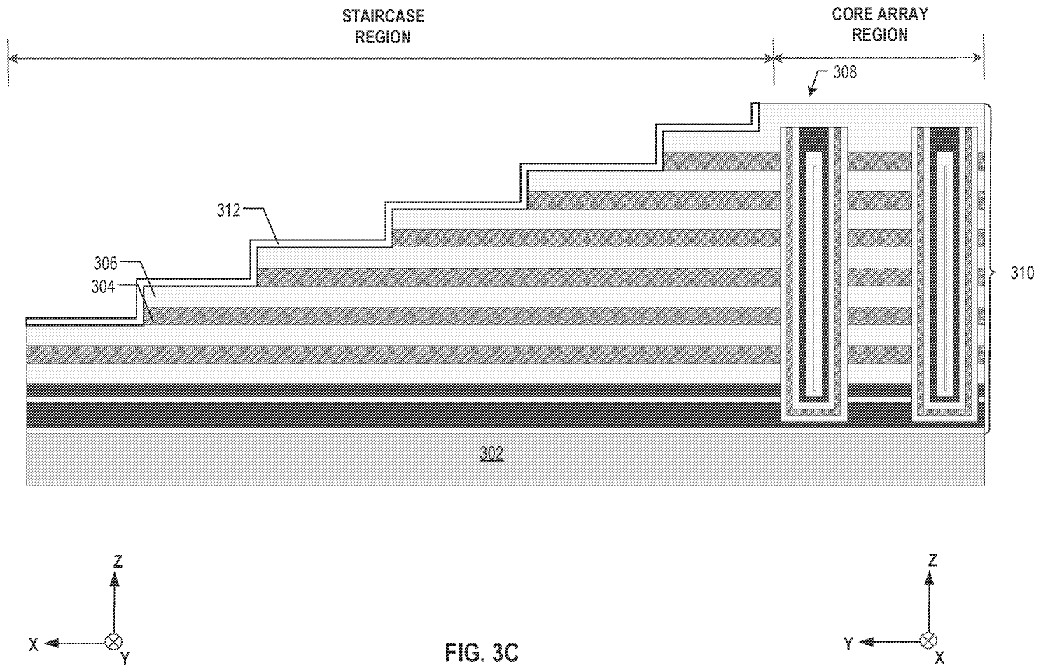

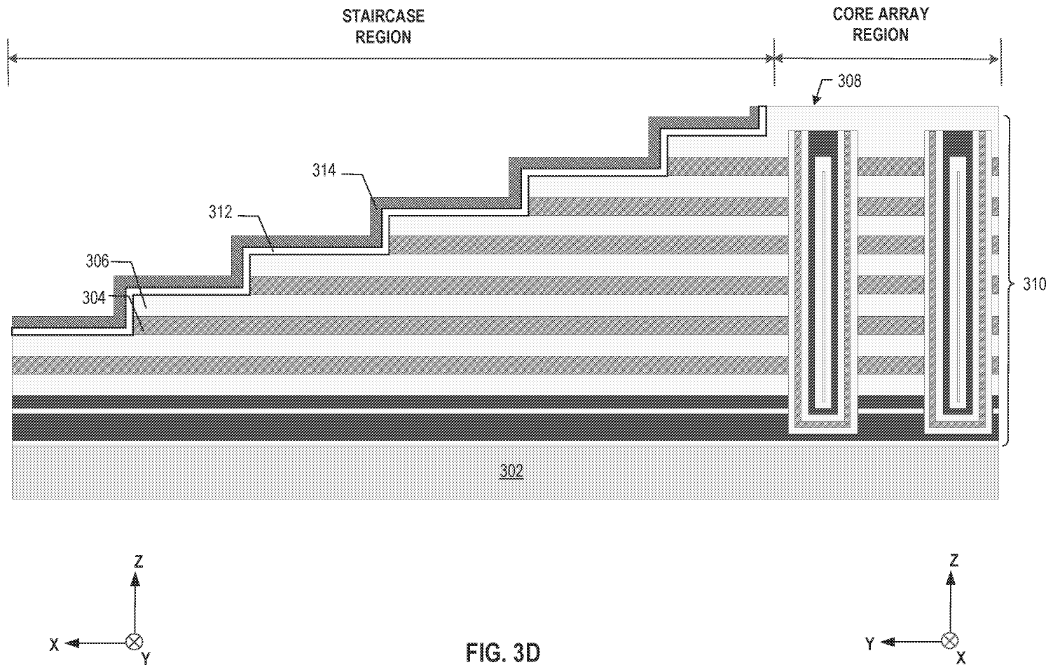

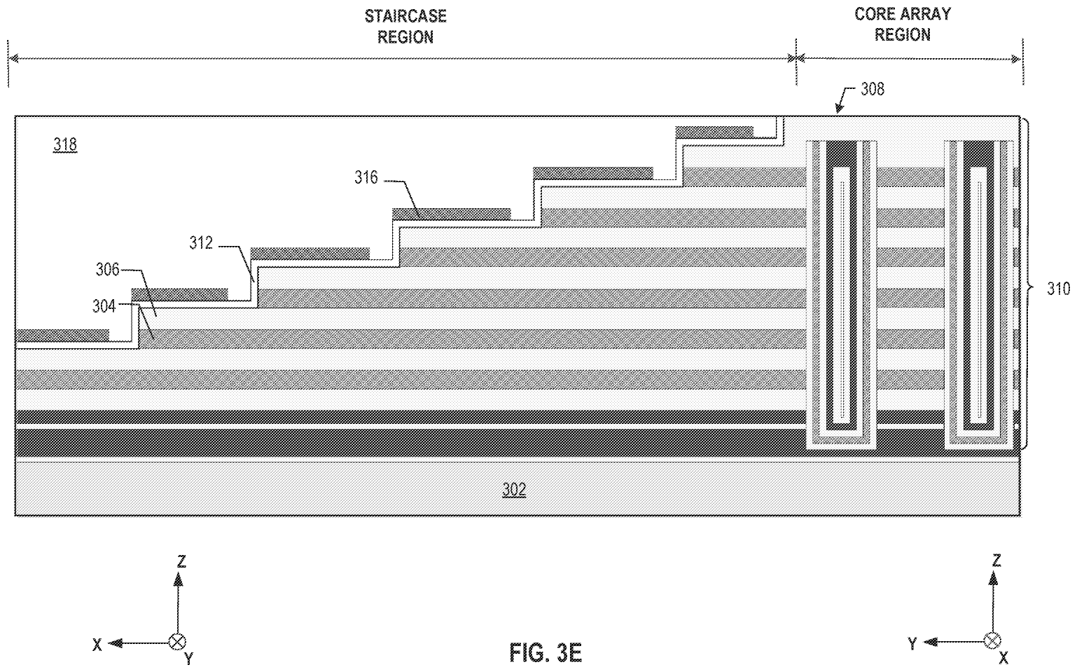

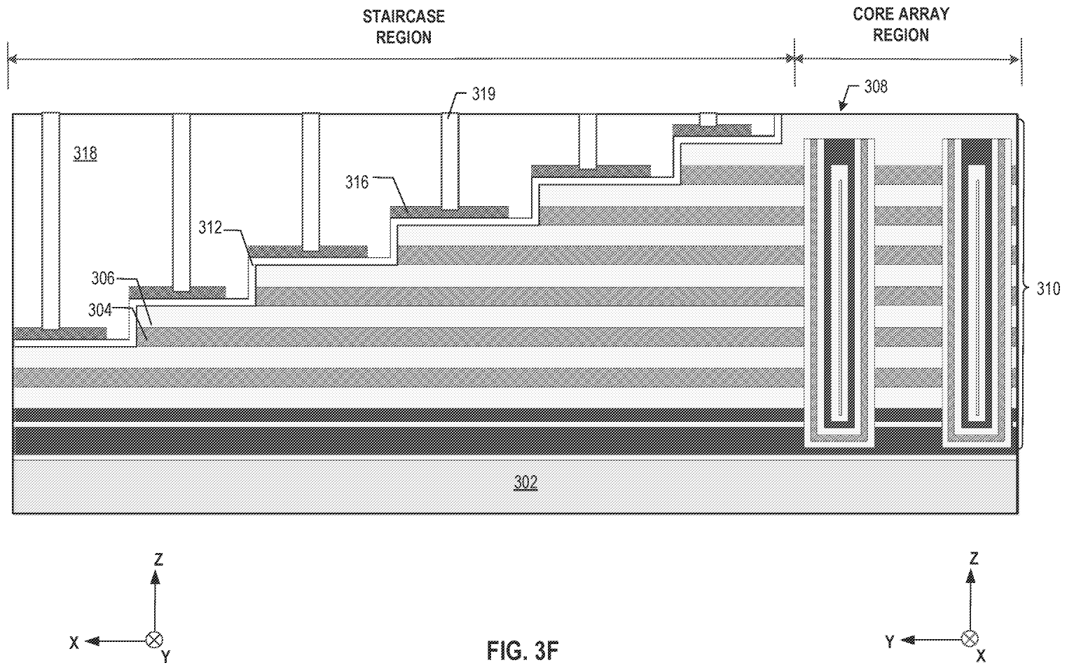

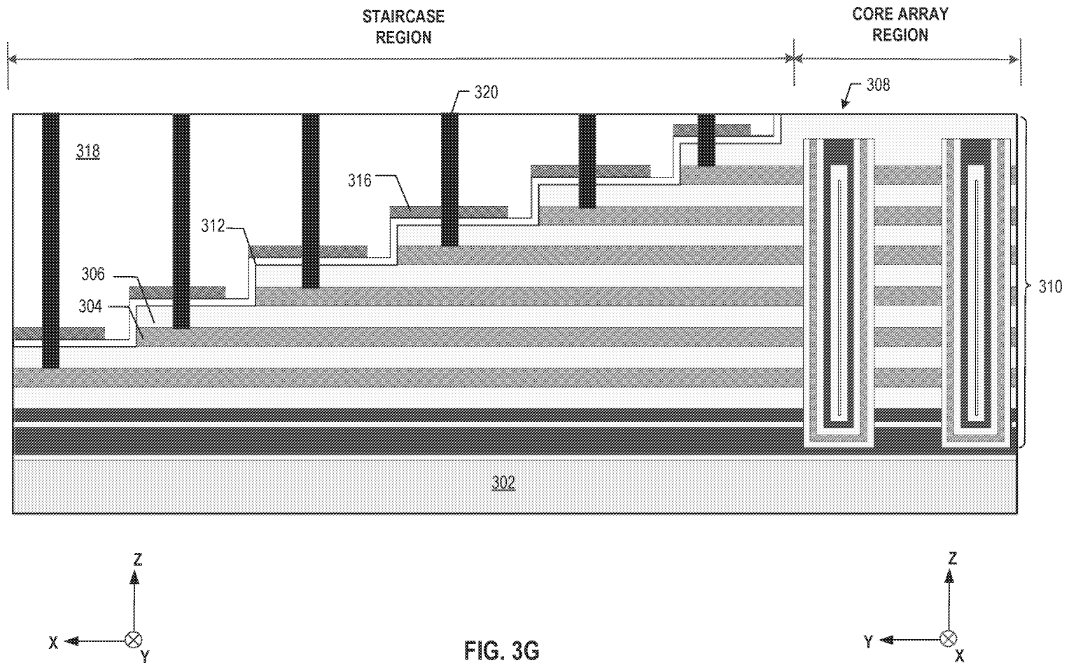

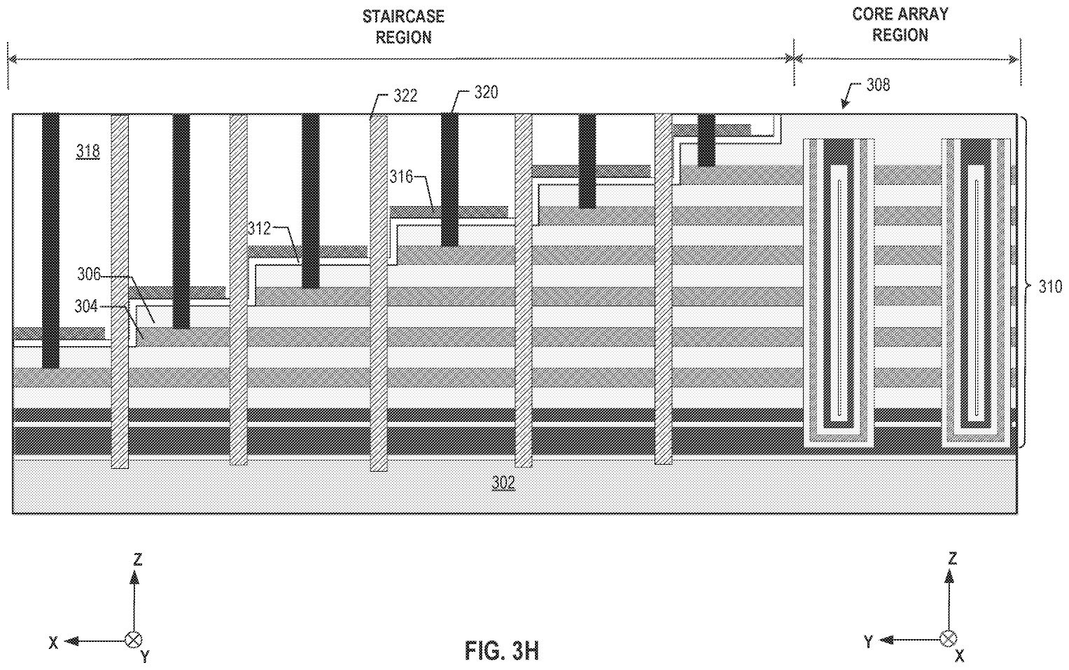

As shown in FIGS. 2A-2E, 3D memory devices 200, 201, 202, 203 may each include a stack structure over a substrate. For ease of description, substrate 218 is employed to represent the respective substrate in each of 3D memory devices 200-203. Substrate 218 may include silicon (e.g., single crystalline silicon), silicon germanium (SiGe), gallium arsenide (GaAs), germanium (Ge), silicon on insulator (SOI), germanium on insulator (GOI), or any other suitable materials. In some implementations, substrate 218 is a thinned substrate (e.g., a semiconductor layer), which was thinned by grinding, etching, chemical mechanical polishing (CMP), or any combination thereof. It is noted that x and y axes are included in the figures of the present disclosure to further illustrate the spatial relationship of the components in each of 3D memory devices 200-203. Substrate 218 of the respective 3D memory device includes two lateral surfaces (e.g., a top surface and a bottom surface) extending laterally in the x- and y-directions (i.e., the lateral direction), which are orthogonal to the z-direction (i.e., the vertical direction). As used herein, whether one component (e.g., a layer or a device) is “on,” “above,” or “below” another component (e.g., a layer or a device) of a 3D memory device (e.g., each one of 3D memory device 200-203) is determined relative to substrate 218 of the respective 3D memory device in the z-direction (i.e., the vertical direction) when substrate 218 is positioned in the lowest plane of the 3D memory device in the z-direction. The same notion for describing spatial relationships is applied throughout the present disclosure.

3D memory devices 200-203 may each be part of a monolithic 3D memory device. The term “monolithic” means that the components (e.g., the peripheral device and memory array device) of the 3D memory device are formed on a single substrate. For monolithic 3D memory devices, the fabrication encounters additional restrictions due to the convolution of the peripheral device processing and the memory array device processing. For example, the fabrication of the memory array device (e.g., NAND memory strings) is constrained by the thermal budget associated with the peripheral devices that have been formed or to be formed on the same substrate.

Alternatively, 3D memory devices 200-203 may each be part of a non-monolithic 3D memory device, in which components (e.g., the peripheral device and memory array device) may be formed separately on different substrates and then bonded, for example, in a face-to-face manner. In some implementations, the memory array device substrate (e.g., substrate 218) remains as the substrate of the bonded non-monolithic 3D memory device, and the peripheral device (e.g., including any suitable digital, analog, and/or mixed-signal peripheral circuits used for facilitating the operation of 3D memory devices 200-203, such as page buffers, decoders, and latches; not shown) is flipped and faces down toward the memory array device (e.g., NAND memory strings) for hybrid bonding. It is understood that in some implementations, the memory array device substrate is flipped and faces down toward the peripheral device (not shown) for hybrid bonding, so that in the bonded non-monolithic 3D memory device, the memory array device is above the peripheral device. The memory array device substrate may be a thinned substrate (which is not the substrate of the bonded non-monolithic 3D memory device), and the back-end-of-line (BEOL) interconnects of the non-monolithic 3D memory device may be formed on the backside of the thinned memory array device substrate.

In some implementations, 3D memory devices 200-203 are each a NAND Flash memory device in which memory cells are provided in the form of an array of NAND memory strings each extending vertically above substrate 218. As shown in FIGS. 2A-2E, 3D memory devices 200-203 may each include a stack structure formed on substrate 218, and NAND memory strings may each include a channel structure 214 extending vertically through the stack structure in the z-direction. Although not shown, 3D memory devices 200-203 may each include a plurality of channel contacts, conductively connected to channel structures 214 and bit lines (not shown). For example, each channel structure 214 may be conductively connected to a respective bit line through a channel contact. The channel contacts may include a suitable conductive material such as tungsten. The NAND memory strings are located in the core array region of the respective 3D memory device. The stack structures may each include interleaved a plurality of conductive layers 210 and a plurality of dielectric layers 208. As shown in FIGS. 2A-2E, edges of conductive layers 210 and dielectric layers 208 form a plurality of stairs extending in the x-direction. In FIG. 2A, the stairs are illustrated in dashed lines. Conductive layers 210 may extend laterally, coupling a plurality of memory cells, and function as gate conductors of memory cells in a NAND memory string. In some implementations, a pair of conductive layer 210 and dielectric layer 208 are arranged in a stair. In some implementations, more than one pair of conductive layers 210 and dielectric layers 208 are arranged in a stair.

Conductive layers 210 may include at least one source select gate line, a plurality of word lines, and at least one drain select gate line. Conductive layers 210 may each include conductive materials including, but not limited to, tungsten (W), cobalt (Co), copper (Cu), aluminum (Al), polysilicon, doped silicon, silicides, or any combination thereof. Dielectric layers 208 may each include dielectric materials including, but not limited to, silicon oxide, silicon nitride, silicon oxynitride, or any combination thereof.

In some implementations, channel structure 214 includes a semiconductor channel, a memory film (including a tunneling layer, a storage layer, and a blocking layer). The channel structure may include a channel hole filled with semiconductor materials (e.g., as a semiconductor channel) and dielectric materials (e.g., as a memory film). In some implementations, the semiconductor channel includes silicon, such as amorphous silicon, polysilicon, or single crystalline silicon. In some implementations, the memory film is a composite layer including a tunneling layer, a storage layer (also known as a “charge trap layer”), and a blocking layer. In some implementations, the remaining space of the channel structure may be partially or fully filled with a filling layer including dielectric materials, such as silicon oxide. The channel structure may have a cylinder shape (e.g., a pillar shape). The filling layer, the semiconductor channel, the tunneling layer, the storage layer, and the blocking layer are arranged radially from the center toward the outer surface of the channel structure 214 in this order, according to some implementations. The tunneling layer may include silicon oxide, silicon oxynitride, or any combination thereof. The storage layer may include silicon nitride, silicon oxynitride, silicon, or any combination thereof. The blocking layer may include silicon oxide, silicon oxynitride, high dielectric constant (high-k) dielectrics, or any combination thereof. In one example, the memory film may include a composite layer of silicon oxide/silicon oxynitride (or silicon nitride)/silicon oxide (ONO).

In some implementations, in 3D memory devices 200, 201, 202, a high-k dielectric layer is disposed between the outer surface of channel structure 214 and the memory film, and no high-k dielectric layer is disposed over conductive layer 210 as gate dielectric layers. For example, the gate dielectric layer in 3D memory devices 200, 201, 202 does not include a high-k dielectric layer/material. The high-k dielectric layer may include any suitable material such as aluminum oxide, hafnium silicate, zirconium silicate, hafnium oxide, zirconium oxide, or any combination thereof. Meanwhile, in 3D memory device 203, no high-k dielectric layer is disposed between the outer surface of channel structure 214 and the memory film. Instead, a high-k dielectric layer is disposed over conductive layer 210 as part or entirety of the gate dielectric layer.

In some implementations, the NAND memory string may further include a channel contact, or called semiconductor plug, in a lower portion (e.g., at the lower end) of NAND memory string below the channel structure. As used herein, the “upper end” of a component (e.g., NAND memory string) is the end farther away from substrate 218 in the z-direction, and the “lower end” of the component (e.g., NAND memory string) is the end closer to substrate 218 in the z-direction when substrate 218 is positioned in the lowest plane of the respective 3D memory device. The channel contact may include a semiconductor material, such as silicon, which is epitaxially grown from substrate 218 in any suitable direction. It is understood that in some implementations, the channel contact includes single crystalline silicon, the same material as substrate 218. In other words, the channel contact may include an epitaxially-grown or deposited semiconductor layer that is the same as the material of substrate 218. In some implementations, part of the channel contact is above the top surface of substrate 218 and in contact with the semiconductor channel. The channel contact may function as a channel controlled by a source select gate of NAND memory string. It is understood that in some implementations, one or more of 3D memory devices 200, 201, 202, 203 does not include a channel contact.

In some implementations, NAND memory string further includes a channel plug in an upper portion (e.g., at the upper end) of NAND memory string. The channel plug may be in contact with the upper end of the semiconductor channel. The channel plug may include semiconductor materials (e.g., polysilicon). By covering the upper end of the channel structure during the fabrication of 3D memory device 200/201, the channel plug may function as an etch stop layer to prevent the etching of dielectrics filled in the channel structure, such as silicon oxide and silicon nitride. In some implementations, the channel plug also functions as the drain of NAND memory string. It is understood that in some implementations, 3D memory device 100 does not include a channel plug.

As shown in FIGS. 2A-2E, 3D memory devices 200, 201, 202, 203 may also each include one or more slit structures 224 extending in the respective stack structure, e.g., in the x- and z-directions in the core array region and the staircase region. Slit structures 224 may also be referred to as gate-line slits, in some implementations. A source contact structure may be formed in slit structure 224. The source contact structure may be part of the source of each of 3D memory devices 200-203 and may apply source voltages on the respective 3D memory device. Although not shown, the source contact structure may include a dielectric spacer and a source contact in the dielectric spacer. The source contact may include conductive materials including, but not limited to, tungsten (W), cobalt (Co), copper (Cu), aluminum (Al), polysilicon, doped silicon, silicides, or any combination thereof. The dielectric spacer may include dielectric materials including, but not limited to, silicon oxide, silicon nitride, silicon oxynitride, or any combination thereof.

As shown in FIGS. 2B-2E, 3D memory devices 200-203 may each include a dielectric structure 222 disposed over the stairs and a plurality of word line contacts 216 (e.g., interconnect structures) extending in dielectric structure 222. Each word line contact 216 may be landed on (e.g., in contact with) conductive layer 210 of the respective stair. Word line contacts 216 may apply word line voltages on conductive layers 210 for the operation of the respective 3D memory device. Word line contacts 216 may each include conductive materials including, but not limited to, tungsten (W), cobalt (Co), copper (Cu), aluminum (Al), polysilicon, doped silicon, silicides, or any combination thereof. Dielectric structure 222 may each include dielectric materials including, but not limited to, silicon oxide, silicon nitride, silicon oxynitride, or any combination thereof.

As shown in FIGS. 2B-2E, 3D memory devices 200, 201, 202, 203 may each include one or more support structures 212 extending in the respective stack structure, e.g., in the z-direction. Support structures 212 may also extend in dielectric structure 222, if any. In various implementations, support structures 212 may be located in the staircase region and/or the core array region of the respective 3D memory device. Support structures 212 may each have a pillar shape, and may extend vertically into substrate 218. In some implementations, a bottom surface of support structure 212 is below the top surface of substrate 218. Support structures 212 may provide support to the respective stack structure during the fabrication such that the stack structure is less susceptible to collapse. Support structures 212 may not be in contact with word line contacts 216 (e.g., interconnect structures) laterally or vertically. In some implementations, the orthogonal projections of support structures 212 do not overlap with orthogonal projections of word line contacts 216 on the x-y plane. Support structures 212 may each include dielectric materials including, but not limited to, silicon oxide, silicon nitride, silicon oxynitride, or any combination thereof.

3D memory devices 200, 201, 202 may each include a stack structure 220 in which, for each stair, dielectric layer 208 is above and in contact with the respective conductive layer 210. As shown in FIGS. 2B-2D, 3D memory devices 200, 201, 202 may each include a cover dielectric layer 206 extending on the stairs. Cover dielectric layer 206 may cover at least the lateral surfaces (e.g., in the x-y plane) of the stairs. In some implementations, cover dielectric layer 206 may cover one or more vertical surfaces (e.g., in the z-x plane) of the stairs. For example, cover dielectric layer 206 may extend continuously over the stairs in each of 3D memory devices 200, 201, 202. In some implementations, cover dielectric layer 206 may include an insulating (e.g., a dielectric) material such as silicon oxide, silicon oxynitride, or any combination thereof. For example, cover dielectric layer 206 may include silicon oxide. In some implementations, cover dielectric layer 206 may improve the isolation between the conductive layers (e.g., formed from the sacrificial layers) and the conductive portions (e.g., formed from the sacrificial portions), and reduce the overetching of sacrificial portions and sacrificial layers during the gate replacement. In some implementations, cover dielectric layer 206 may increase the landing window of word line contacts 216 in the z-direction. In various implementations, the material of cover dielectric layer 206 can be the same as or different from that dielectric layer 208.

3D memory devices 200, 201, and 202 may each include a landing structure at each of the stairs, on the respective conductive layer 210. The fabrication process of the landing structure may reduce the damage to the respective conductive layer 210 during the fabrication process, and may increase the landing window (e.g., in the z-direction) of word line contacts 216. As shown in FIG. 2B, 3D memory device 200 may include a plurality of landing structures 231 each disposed on, e.g., above and in contact with, the respective conductive layer 210 of each stair. Landing structure 231 may include a first layer and a second layer, each over conductive layer 210. The first layer may be over the second layer. In some implementations, the first layer includes a conductive portion 204, and the second layer includes a cover dielectric portion 206a and a dielectric portion 208a. In some implementations, dielectric portion 208a is above and in contact with conductive layer 210, a cover dielectric portion 206a is above and in contact with dielectric portion 208a, and a conductive portion 204 is above and in contact with cover dielectric portion 206a. Dielectric portion 208a may be the portion of dielectric layer 208 at the landing area, which represents the lateral area of a stair for receiving a respective word line contact 216, and is the lateral area between the edges of adjacent stairs. In some implementations, the first layer may exceed the edge of the respective stair such that the side surface is beyond the edge of the stair. As shown in FIGS. 2B-2D, the first layer may extend beyond the edge of the respective stair due to the non-zero thickness of cover dielectric layer 206. For example, a landing area may be represented by the stair between the dotted lines in FIG. 2A.

Dielectric portion 208a may include the same material as dielectric layer 208, such as silicon oxide, silicon oxynitride, or any combination thereof. Cover dielectric portion 206a may be the lateral portion of cover dielectric layer 206 in the landing area, and may include the same material as cover dielectric layer 206, such as silicon oxide, silicon oxynitride, or any combination thereof. Conductive portion 204 may include the same material as conductive layer 210, such as tungsten (W), cobalt (Co), copper (Cu), aluminum (Al), polysilicon, doped silicon, silicides, or any combination thereof. In some implementations, conductive portion 204 includes of a conductive material. For example, conductive portion 204 consists of tungsten and a liner material between the tungsten and the boundary of conductive portion 204. For example, the adhesive liner material may include titanium nitride. In some implementations, 3D memory device 200 may include a plurality of conductive portions 204, each disposed on a respective stair and disconnected from one another. For example, orthogonal projections of adjacent conductive portions 204 do not overlap with each other in the x-y plane.

As shown in FIG. 2C, 3D memory device 201 may include a plurality of landing structures 232 each disposed on, e.g., above and in contact with, the respective conductive layer 210 of each stair. Landing structure 232 may include a first layer, a second layer, and a third layer, each over conductive layer 210. In the x-direction, y-direction, and/or z-direction, the first layer may surround the third layer, partially or fully. The first layer and the third layer may each be over the second layer. In some implementations, the first layer includes a conductive portion 205, the third layer includes a filler layer 224, and the second layer includes a cover dielectric portion 206a and a dielectric portion 208a. Dielectric portion 208a and a cover dielectric portion 206a may be similar to those in 3D memory device 200, and the detailed description is not repeated.

Different from conductive portion 204 in 3D memory device 200, conductive portion 205 does not fill the space inside. Instead, filler layer 224 is disposed inside conductive portion 205 such that conductive portion covers at least the lateral surfaces (e.g., upper and lower surfaces) of filler layer 224. In some implementations, conductive portion 205 fully surrounds filler layer 224 laterally and vertically. In some implementations, conductive portion 205 covers only the lateral surfaces of filler layer 224. Conductive portion 205 may include the same material as conductive layer 210, such as tungsten (W), cobalt (Co), copper (Cu), aluminum (Al), polysilicon, doped silicon, silicides, or any combination thereof. In some implementations, conductive portion 205 consists of tungsten and a linear layer such as TiN. In some implementations, filler layer 224 includes silicon oxide, silicon nitride, silicon oxynitride, polysilicon, carbon, airgap, or any combination thereof. In some implementations, 3D memory device 200 may include a plurality of conductive portions 205, each disposed on a respective stair and disconnected from one another. For example, orthogonal projections of adjacent conductive portions 205 do not overlap with each other in the x-y plane.

As shown in FIG. 2D, 3D memory device 202 may include a plurality of landing structures 234, each disposed on, e.g., above and in contact with, the respective conductive layer 210 of each stair. Landing structure 234 may include a first layer and a second layer, each over conductive layer 210. The first layer may be over the second layer. In some implementations, the first layer includes a filler portion 226, and the second layer includes a cover dielectric portion 206a and a dielectric portion 208a. Dielectric portion 208a and a cover dielectric portion 206a may be similar to those in 3D memory device 200, and the detailed description is not repeated.

Different from 3D memory devices 200 and 201, 3D memory device 202 includes a filler portion 226 instead of a conductive portion. Filler portion 226 may be disposed above and in contact with a respective cover dielectric portion 206a. In some implementations, 3D memory device 202 may include a plurality of filler portions 226, each disposed on a respective stair and be disconnected from each other. In some implementations, filler portion 226 includes a material different from that of conductive layer 210, such as silicon oxide, silicon nitride, silicon oxynitride, polysilicon, carbon, or any combination thereof.

As shown in FIG. 2E, 3D memory device 203 may include a stack structure 221 in which, for each stair, conductive layer 210 is above and in contact with the respective dielectric layer 208. Different from 3D memory devices 200-202, 3D memory device 203 may not include a cover dielectric layer. 3D memory device 203 may include a landing structure at each of the stairs, on the respective conductive layer 210. The fabrication process of the landing structure may increase the landing window of word line contacts 216. As shown in FIG. 2E, 3D memory device 203 may include a plurality of landing structures 236, each disposed on, e.g., above and in contact with, the respective conductive layer 210 of each stair. Landing structure 236 may include a first layer and a second layer, each over conductive layer 210. The first layer may be over the second layer. In some implementations, the first layer partially or fully covers the second layer. For example, the first layer may partially or fully surround the second layer. In some implementations, the first layer covers at least the lateral surfaces (e.g., the upper surface) of the second layer. In some implementations, the first layer includes a conductive portion 228, which includes the same material as conductive layer 210, such as tungsten (W), cobalt (Co), copper (Cu), aluminum (Al), polysilicon, doped silicon, silicides, or any combination thereof. In some implementations, the second layer includes a filler layer 230, which includes a different material from conductive portion 228. Filler layer 230 may include silicon oxide, silicon nitride, silicon oxynitride, polysilicon, carbon, airgap, or any combination thereof. Filler layer 230 may be disposed between conductive portion 228 and conductive layer 210. In some implementations, conductive portion 228 fully surrounds filler layer 230 laterally and vertically. In some implementations, conductive portion 228 covers only the lateral surfaces of filler layer 230. In some implementations, no filler layer is formed in landing structure 236, and landing structure 236 consists of conductive portion 228 and a liner layer such as TiN. It should be noted that, the location and dimensions of filler layer 230 should not be limited by the illustrations of the present disclosure. In various implementations, the thickness of conductive layer 210 under filler layer 230 may vary and be thinner or thicker than or about the same as the rest of conductive layer 210.

As shown in FIGS. 2B-2E, word line contact 216 may be landed on, e.g., in contact with, conductive layer 210 corresponding to each stair, at the landing area. In some implementations, word line contact 216 may punch through and penetrate the respective landing structure (e.g., any conductive material above conductive layer 210) on the respective stair. The landing window of word line contact 216 may be improved. In some implementations, in 3D memory device 203, conductive portion 228 may be in contact with the respective conductive layer 210, and may improve the electrical connection between word line contact 216 and conductive layer 210. In some implementations, the first layer and cover dielectric layer 206 each includes silicon oxide.

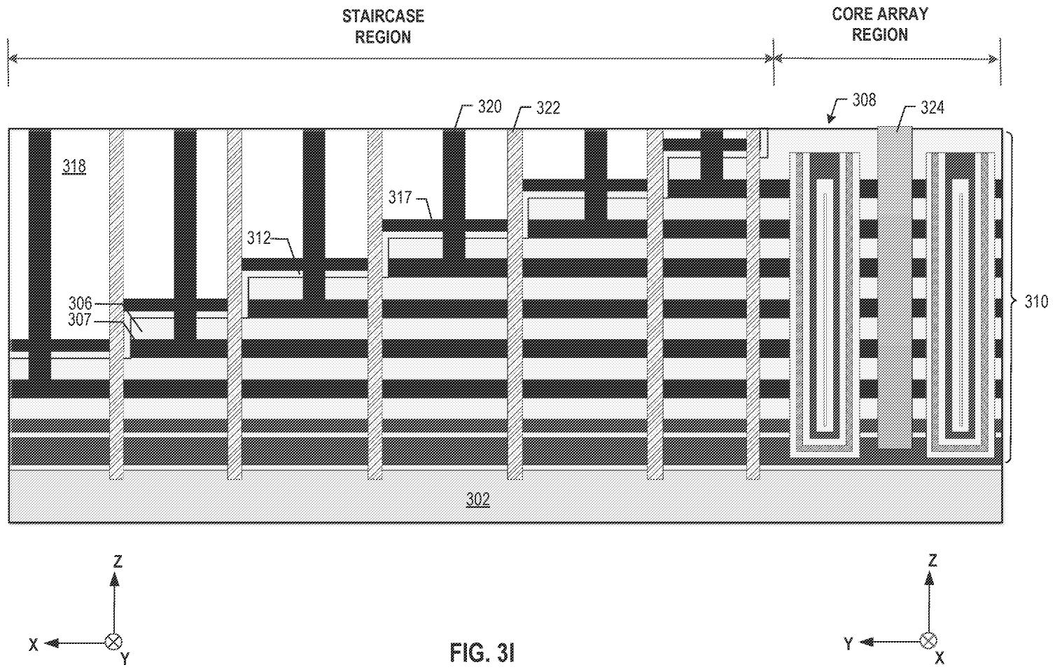

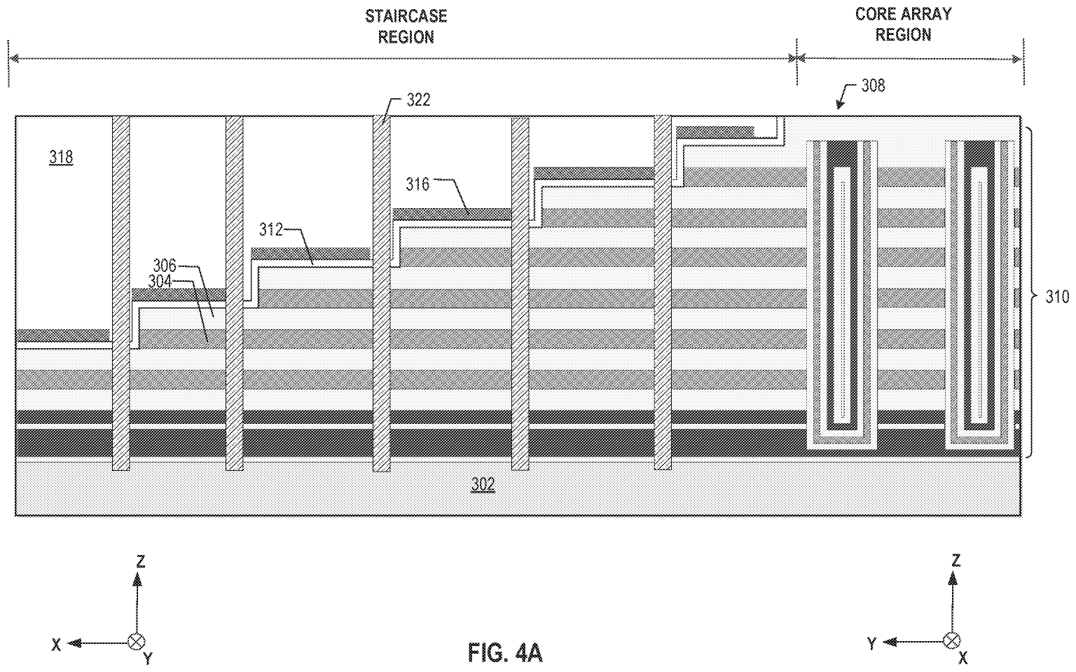

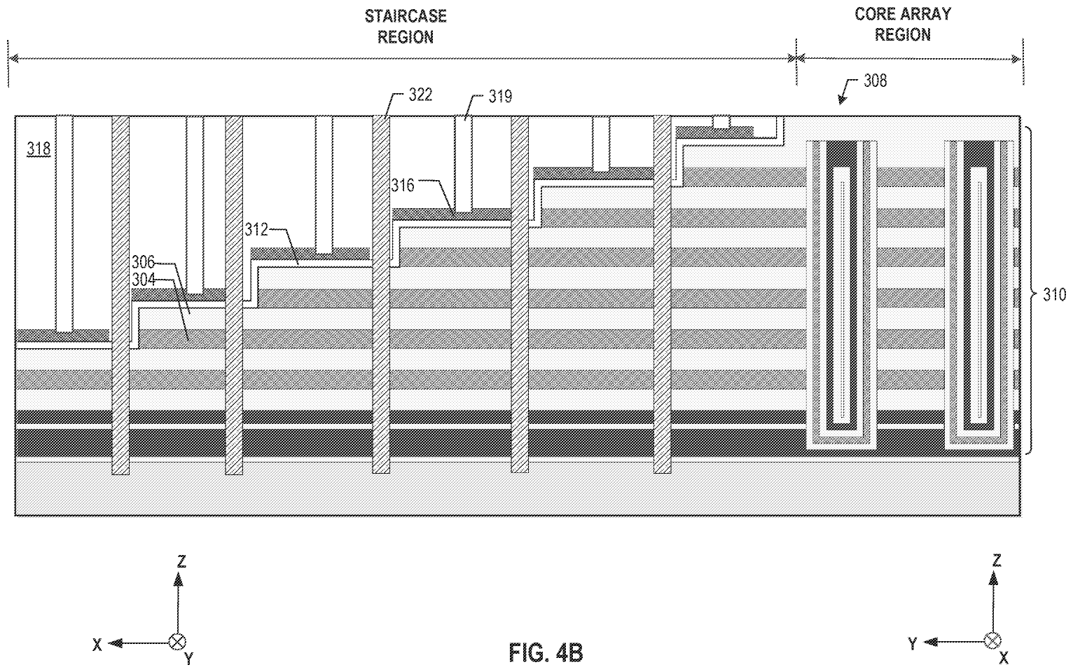

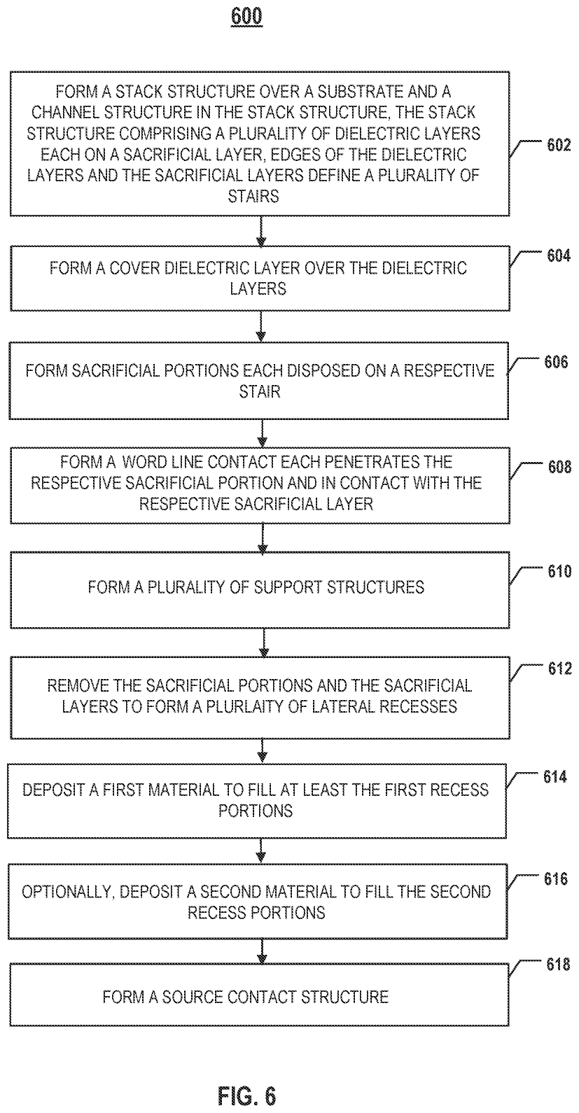

FIGS. 3A-3I illustrate a fabrication process of a 3D memory device, according to some aspects of the present disclosure. FIGS. 4A-4C illustrate part of a fabrication process to form a 3D memory device, according to some aspects of the present disclosure. The 3D memory device may be an example of 3D memory device 200, 201, or 202. FIG. 6 illustrates a flowchart of an exemplary method 600 for forming the 3D memory device, according to some aspects of the present disclosure. For the purpose of better describing the present disclosure, the structures in FIGS. 2B-2D and method 600 in FIG. 6 will be discussed together. It is understood that the operations shown in method 600 are not exhaustive and that other operations may be performed as well before, after, or between any of the illustrated operations. Further, some of the operations may be performed simultaneously, or in a different order than shown in FIGS. 2A-2D and FIG. 6.

As shown in FIG. 6, method 600 starts at operation 602, in which a stack structure is formed over a substrate, and a channel structure is formed in the stack structure. The stack structure includes a plurality of dielectric layers each on a sacrificial layer. Edges of the dielectric layers and the sacrificial layers define a plurality of stairs. FIGS. 3A and 3B illustrate a corresponding structure.

As shown in FIG. 3A, a material stack structure 309 can be formed on a substrate 302. Material stack structure 309 can include interleaved sacrificial material layers 303 and dielectric material layers 305 extending in the x-y plane. A plurality of sacrificial material/dielectric material layer pairs can be formed. In some implementations, each dielectric material layer 305 may include a layer of silicon oxide, and each sacrificial material layer 303 may include a layer of silicon nitride. In some implementations, a pad oxide layer is formed between substrate 302 and sacrificial material layer 303 at the bottom by depositing dielectric materials, such as silicon oxide, on substrate 218. In some implementations, a cap oxide layer is deposited on top of material stack structure 309, or as part of material stack structure 309. Material stack structure 309, the pad oxide layer, and a cap oxide layer, may each be formed by one or more thin film deposition processes including, but not limited to, chemical vapor deposition (CVD), physical vapor deposition (PVD), atomic layer deposition (ALD), or any combination thereof.

Channel structures 308 are formed extending vertically through material stack structure 309 in the z-direction in the core array region. In some implementations, an etch process may be performed to form a channel hole in material stack structure 309. The channel hole may extend vertically through the interleaved sacrificial layers and dielectric layers. In some implementations, fabrication processes for forming the channel hole may include wet etching and/or dry etching, such as deep reactive ion etching (DRIE). In some implementations, the channel hole may extend further into the top portion of substrate 302. The etch process through material stack structure 309 may not stop at the top surface of substrate 218 and may continue to etch part of substrate 302. After the formation of the channel hole, an epitaxial operation, e.g., a selective epitaxial growth operation, may be performed to form a channel contact on the bottom of the channel hole. The channel contact, or called semiconductor plug, can include a semiconductor material, such as silicon, which is epitaxially grown from substrate 302 in any suitable direction. Then, the memory film, including the tunneling layer, the storage layer, the blocking layer, and the semiconductor channel can be formed. In some implementations, a high-k dielectric layer is deposited in the channel hole, prior to the deposition of the memory film. For example, a high-k dielectric layer is deposited between the outer surface of channel structure 308 and the memory film. Optionally, a filling layer may be formed in the channel hole. In some implementations, the channel structure may not include a semiconductor plug. The deposition of the high-k dielectric layer, the memory film, the semiconductor channel, and the filling layer may include any suitable thin-film deposition processes such as CVD, PVD, ALD, or any combination thereof. The deposition of the channel plug may include CVD, PVD, ALD, electroplating, electroless plating, or any combination thereof.

As shown in FIG. 3B, material stack structure 309 can be patterned to form a stack structure 310, which includes a dielectric stack having a plurality of interleaved sacrificial layers 304 and dielectric layers 306, forming a plurality of sacrificial/dielectric layer pairs. Edges of sacrificial/dielectric layer pairs may define a plurality of stairs. The landing area of each stair may be defined as the area of the stair between the vertical surfaces of adjacent stairs. For each stair, a dielectric layer 306 is over and above a respective sacrificial layer 304. The dielectric stack (e.g., the stairs) may be formed by repeatedly trimming material stack structure 309 vertically and horizontally. The trimming of the dielectric material stack may include photolithography and etching (e.g., dry and/or wet etching) processes. In some implementations, for each stair, dielectric layer 306 is above and in contact with sacrificial layer 304.

Referring back to FIG. 6, method 600 proceeds to operation 604, in which a cover dielectric layer is formed over the dielectric layers. FIG. 3C illustrate a corresponding structure.

As shown in FIG. 3C, a cover dielectric layer 312 is formed over dielectric layers 306 of each stair. Cover dielectric layer 312 may be over at least the landing area of each stair. In some implementations, cover dielectric layer 312 is also over the vertical surfaces of the stairs, e.g., in contact with the vertical/side surfaces of dielectric layers 306 and sacrificial layers 304. In some implementations, cover dielectric layer 312 continuously extends laterally (e.g., in the x-direction) and vertically (in the x-direction) on the stairs. The cover dielectric layer may include a dielectric material, such as silicon oxide. The deposition of the cover dielectric layer 312 may include any suitable thin-film deposition processes such as CVD, PVD, ALD. In some implementations, cover dielectric layer 312 is deposited using ALD.

Referring back to FIG. 6, method 600 proceeds to operation 606, in which a plurality of sacrificial portions are formed, each disposed on a respective stair. FIGS. 3D and 3E illustrate corresponding structures.

As shown in FIG. 3D, a layer 314 of a sacrificial material may be deposited over the stairs. Layer 314 may cover at least the landing area of each stair. Layer 314 may be in contact with cover dielectric layer 312 and have the same material as that of sacrificial layers 304, such as silicon nitride. The sacrificial material of layer 314 may also include other suitable materials such that the sacrificial material of layer 314 and sacrificial layers 304 may be removed in the same etching process in the subsequent gate-replacement process. The deposition of layer 314 may include any suitable thin-film deposition processes such as CVD, PVD, ALD, or any combination thereof.

As shown in FIG. 3E, layer 314 may be patterned to form a plurality of sacrificial portions 316 each disposed on a respective stair. Sacrificial portion 316 may be disposed at the landing area of the respective stair, and in contact with the respective portion of cover dielectric layer 312 on the stair. To form sacrificial portions 316, layer 314 may be patterned to remove portions of the sacrificial material deposited on the side surfaces of the stairs. Each sacrificial portion 316 may thus be disconnected from one another. The patterning of layer 314 may include photolithography and an etching process (e.g., dry and/or wet etching).

A dielectric material structure may be deposited over the stairs to cover at least the stairs. The dielectric material structure may then be planarized to form a dielectric structure 318 covering the stairs and sacrificial portions 316. The deposition of the dielectric material structure may include any suitable thin-film deposition processes such as CVD, PVD, ALD, or any combination thereof. The planarization of the dielectric material structure may include a ClVIP and/or a recess etching process.

Referring back to FIG. 6, method 600 proceeds to operation 608, in which a word line contact is formed each penetrates a respective sacrificial portion and in contact with a respective sacrificial layer. FIGS. 3F and 3G illustrate corresponding structures.

As shown in FIG. 3F, a plurality of openings 319 are formed in dielectric structure 318. Openings 319 may extend vertically in dielectric structure 318 and each land on a respective sacrificial portion 316. In some implementations, opening 319 may be in contact with the respective sacrificial portion 316. To form opening 319, an etching process may be performed to form a plurality of openings extending in dielectric structure 318, each opening in contact with (e.g., stops at) a respective sacrificial portion 316. One or more etching processes can then be performed to such opening 319 extends through the respective sacrificial portion 316 and is in contact with the respective sacrificial layer 304. The process of the opening 319 penetrating sacrificial portion 316 and reaching sacrificial layer 304 may also be referred to as a punch-through process. A conductive material may be deposited to fill openings 319. Word line contacts 320, each penetrating the respective sacrificial portion 316 and in contact with the sacrificial layer 304 of the respective stair, can be formed, as shown in FIG. 3G. In some implementations, the conductive material includes tungsten. Openings 319 may be formed by a suitable etching process, e.g., a dry etch and/or a wet etch. The deposition of the conductive material may include any suitable thin-film deposition processes such as CVD, PVD, ALD, electrode-plating, electroless plating, or any combination thereof. In some implementations, word line contacts 320 may also be referred to as interconnect structures. Dielectric structure 318 may be planarized to remove excess conductive material. The planarization of dielectric structure 318 may include a CMP and/or a recess etching process.

Referring back to FIG. 6, method 600 proceeds to operation 610, in which a plurality of support structures are formed. FIG. 3E illustrates a corresponding structure.

As shown in FIG. 3H, a plurality of support structures 322 may be formed. Support structures 322, e.g., support pillars, may extend vertically in stack structure 310. Support structure 322 may be located in the staircase region and/or the core array region. In the staircase region, support structure 322 may extend in stack structure 310 and dielectric structure 318, e.g., in the staircase region. Support structures 322 may include a dielectric material such as silicon oxide. In some implementations, support structures 322 are formed by forming a plurality of openings extending in stack structure 310 and/or dielectric structure 318, and into substrate 302. A dielectric material may be deposited to fill the openings. Dielectric structure 318 may be planarized to remove excess conductive material deposited in operation 608 and the excess dielectric material deposited in operation 610. The planarization of dielectric structure 318 may include one or more CMP and/or one or more recess etching processes.

Referring back to FIG. 6, method 600 proceeds to operation 612, in which the sacrificial layers and the sacrificial portions are removed to form a plurality of lateral recesses.

Sacrificial layers 304 and sacrificial portions 316 are removed from stack structure 310. A plurality of lateral recesses, extending laterally in the x-y plane, may be formed from the removal of sacrificial layers 304 and sacrificial portions 316. To form the lateral recesses, one or more slit structures (e.g., gate line slits) may be formed extending through stack structure 310 in the x-z plane, referring back to FIGS. 2B-2D. The slit structures may each extend laterally in the x-direction. The slit structures may each be in contact or extend into the top portion of substrate 302. In some implementations, the fabrication process for forming the slit structures may include wet etching and/or dry etching, such as deep reactive ion etching (DRIE). An isotropic etching process, such as wet etching, may be performed through the slit structures to remove sacrificial layers 304 and sacrificial portions 316.

The lateral recesses may each include a first recess portion and a second recess portion over and the first recess portion. The first recess portion may be formed from the removal of a respective sacrificial layer 304. In the x-direction, the length of a first recess portion is greater than that of second recess portion. In some implementations, the first recess portion extends laterally to the edge of the respective stair and also intersects with channel structures 308 in stack structure 310. The second recess portion may be formed by the removal of a respective sacrificial portion 316, and is disposed in the landing area of a respective stair. In some implementations, the first recess portion and the second recess portion are separated by cover dielectric layer 312.

Referring back to FIG. 6, method 600 proceeds to operation 614, in which a first material is deposited into each of the lateral recesses to fill at least the first recess portions. FIG. 3I illustrates a corresponding structure.

As shown in FIG. 3I, a first material may be deposited through the slit structures into the lateral recesses. The first material may fill at least the first recess portions, forming a plurality of conductive layers 307. Depending on the thickness of the second recess portions (or sacrificial portions 316), the second recess portions may or may not be filled by the first material. For example, the second recess portions may be partially filled (e.g., if sacrificial portions 316 was sufficiently thick) or fully filled (e.g., if sacrificial portions 316 was sufficiently thin). In some implementations, when a thickness of sacrificial portion 316 (e.g., layer 314) is less than or equal to 55 nm, the first material fills the second recess portions. In other words, the second recess portions and the first recess portions are each filled with a layer of a single material, e.g., the first material, referring back to 3D memory device 200 in FIG. 2B. A conductive portion 317 may be formed in each second recess portion. The first material may include a conductive material, such as tungsten, and can be formed by any suitable thin-film deposition processes such as CVD, PVD, ALD, electroplating, electroless plating, or any combination thereof. In some implementations, no high-k dielectric material is deposited into the lateral recesses as gate dielectric layers. In various implementations, the thickness of sacrificial portion 316 can be in any other suitable range to form 3D memory device 200.

Referring back to FIG. 6, method 600 proceeds to operation 616, in which, optionally, a second material is deposited to fill the second recess portions. FIGS. 2C and 2D illustrate corresponding structures.

As shown in FIGS. 2C and 2D, when the thickness of sacrificial portion 316 is greater than or equal to 55 nm, a second material, different from the first material may be deposited to fill the second recess portions. In some implementations, after the deposition of the first material in operation 614, a recess etching process may be performed, e.g., to remove excess first material deposited on the side surfaces of the slit structures. The recess etch may also partially or fully remove the first material in the second recess portions. The second material may be deposited after the recess etch. In various implementations, the thickness of sacrificial portion 316 can be in any other suitable range to form 3D memory devices 201 and 202.

In some implementations, the first material may be partially removed from a second recess portion, and may be retained on at least one of the upper and lower surfaces of the second recess portion. For example, the first material may be retained as two layers on both the upper and lower surfaces of the second recess portion, and a layer of the second material is disposed between the two layers of the first material, as referring back to 3D memory device 201 in FIG. 2C. The two layers of the first material, in the second recess portion, may or may not be in contact with each other, e.g., on the vertical surfaces of the second recess portion. In some implementations, the two layers of the first material are separated by the layer of the second material. In some implementations, the first material may be fully removed from a second recess portion, and the second recess portion is filled with a single layer of the second material, as referring back to 3D memory device 201 in FIG. 2D. The second material may include silicon oxide, silicon nitride, silicon oxynitride, polysilicon, carbon, airgap, or any combination thereof. In some implementations, the second material includes silicon oxide. The deposition of the second material may include any suitable thin-film deposition processes such as CVD, PVD, ALD, or any combination thereof. In some implementations, when the second material includes (e.g., or is) airgap, the airgap can be formed by not filling or partially filling the second recess portion.

Referring back to FIG. 6, method 600 proceeds to operation 618, in which a source contact structure is formed in the slit structure. FIG. 3I illustrates a corresponding structure.

As shown in FIG. 3I, a source contact structure 324 is formed in a slit structure. Optionally, one or more recess etching processes may be performed to remove excess materials deposited on the sidewall of the slit structure. The recess etching may include a dry and/or a wet etching process.

A source contact structure 324 may then be formed in the slit structure. The source contact structure may include a dielectric spacer (e.g., silicon oxide) and a source contact (e.g., W) in the dielectric spacer. In some implementations, the formation of the dielectric spacer may include one or more thin filmed deposition processes such as CVD, PVD, and/or ALD. in some implementations, the formation of the source contact may include CVD, PVD, ALD, electroplating, electroless plating, or any combination thereof.

By forming word line contacts 320 prior to support structures 322, contact or over etch of support structures 322 due to fabrication can be reduced or avoided. In some implementations, the density of support structures 322 formed in process shown in FIGS. 3I-3I is desirably high, e.g., equal to or higher than that formed in FIGS. 4A-4C.

FIGS. 4A-4C illustrate part of another fabrication process to form a 3D memory device. The operations shown in FIGS. 4A-4C may be similar to those in method 600 but have a different order. The 3D memory device formed using the process shown in FIGS. 4A-4C may be the same as that formed in FIGS. 3A-3I. In some implementations, as shown in FIGS. 4A-4C, operation 610 is performed after operation 606, and prior to operation 608.

As shown in FIG. 4A, after the formation of sacrificial portions 316 (e.g., operation 606 in method 600), support structures 322 may be formed extending in stack structure 310 and dielectric structure 318. In some implementations, support structures 322 are formed prior to the word line contacts (e.g., 320). The spacing between adjacent support structures 322 may be sufficiently large for the word line contacts to be formed subsequently. The material and process to form support structure 322 may be referred to the description of FIG. 3H, and the detailed description is not repeated herein.

As shown in FIGS. 4B and 4C, after the formation of support structures 322, word line contacts 320 may be formed. Each word line contact 320 may penetrate respective sacrificial portion 316 and in contact with the respective sacrificial layer 304. The material and process to form word line contacts 320 may be referred to the description of FIGS. 3F and 3G, and the detailed description is not repeated herein. In some implementations, operation 612 is performed after operation 608, e.g., the formation of word line contacts 320.

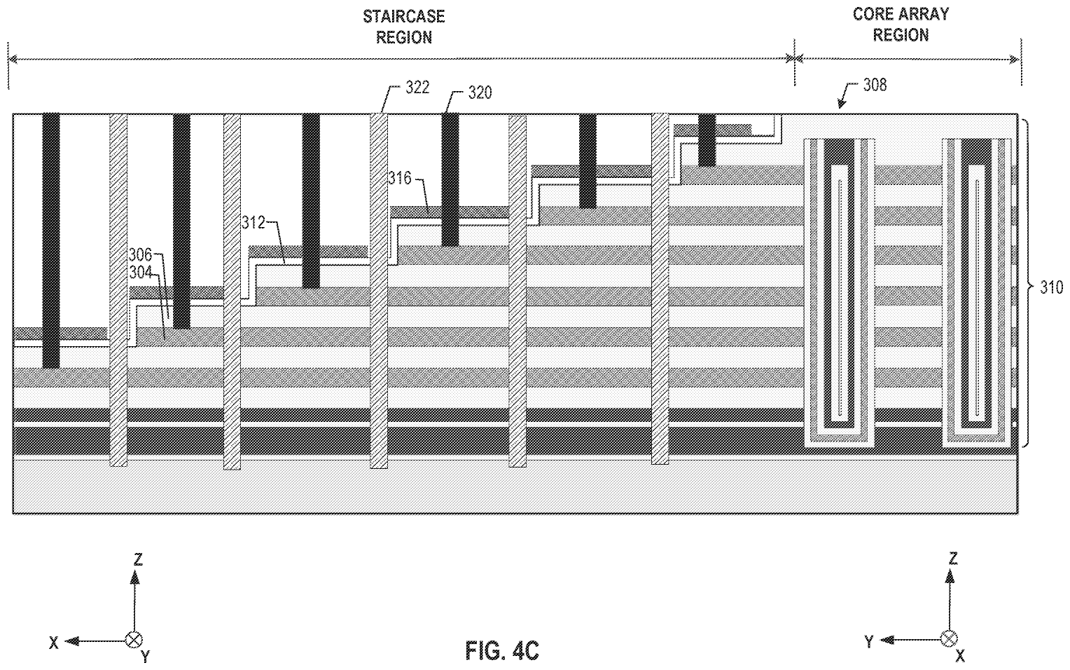

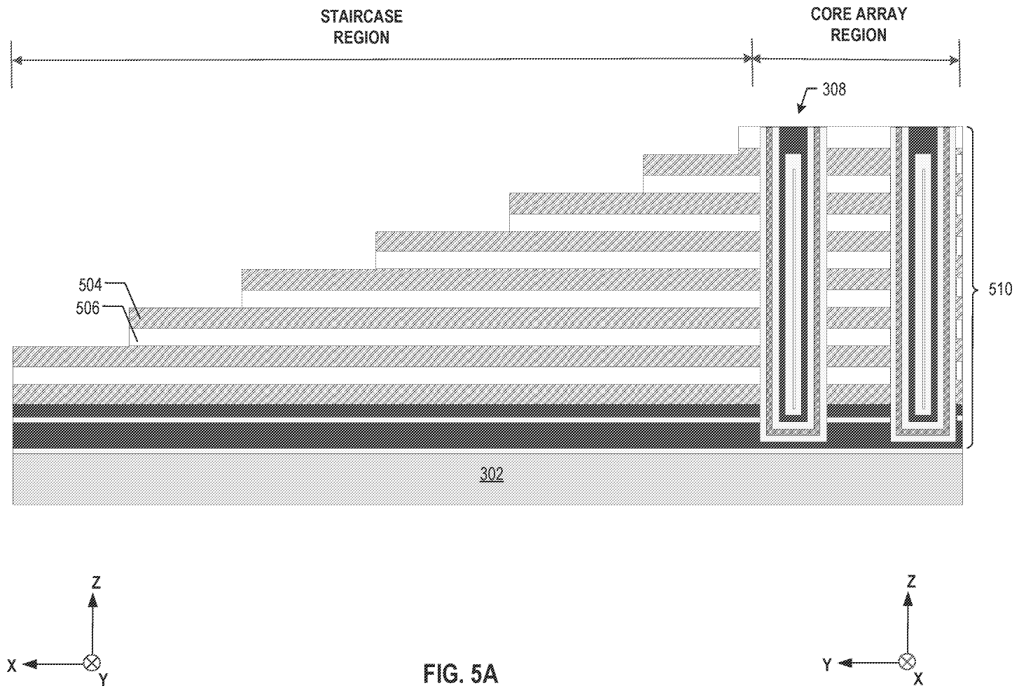

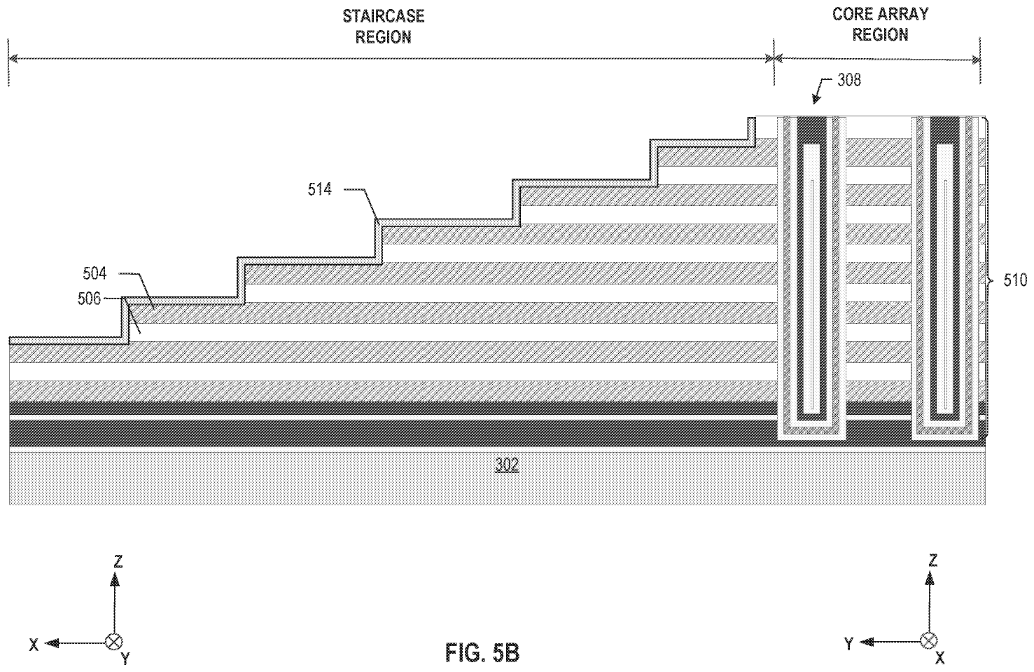

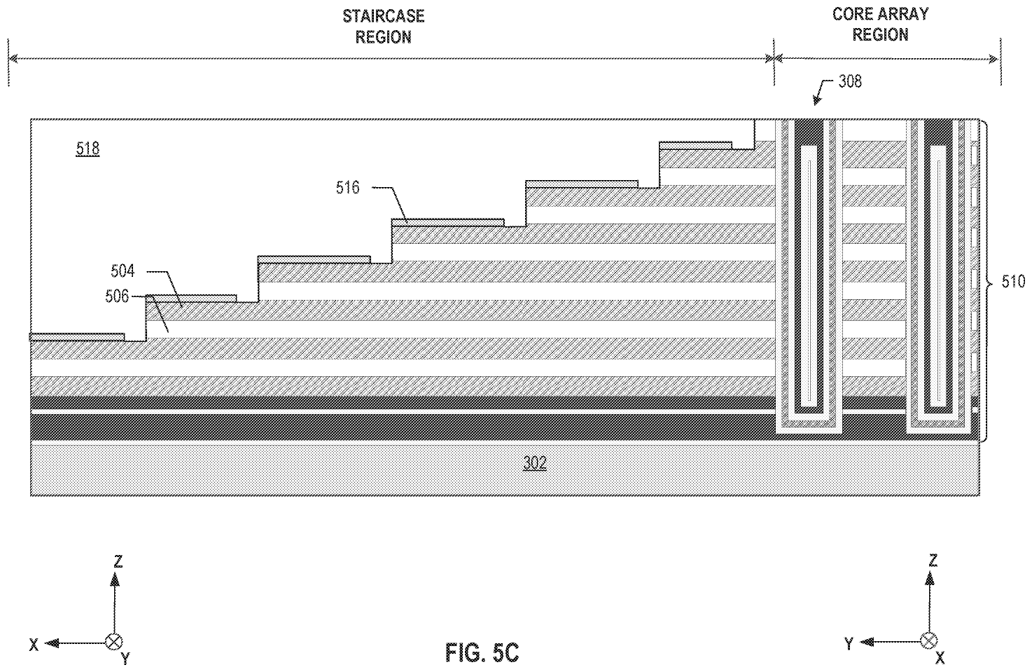

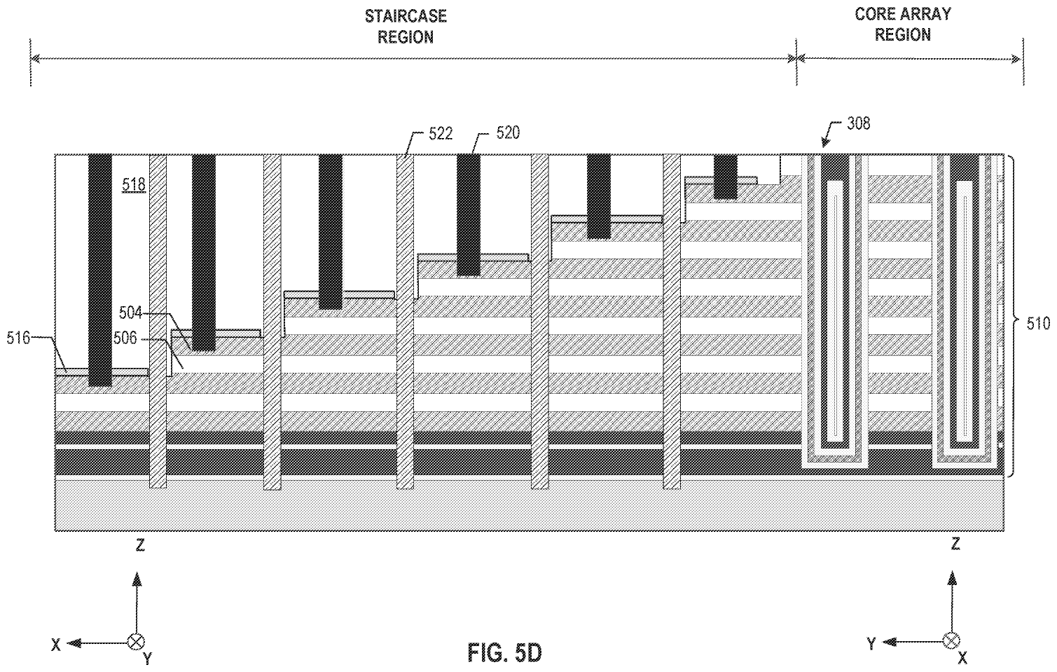

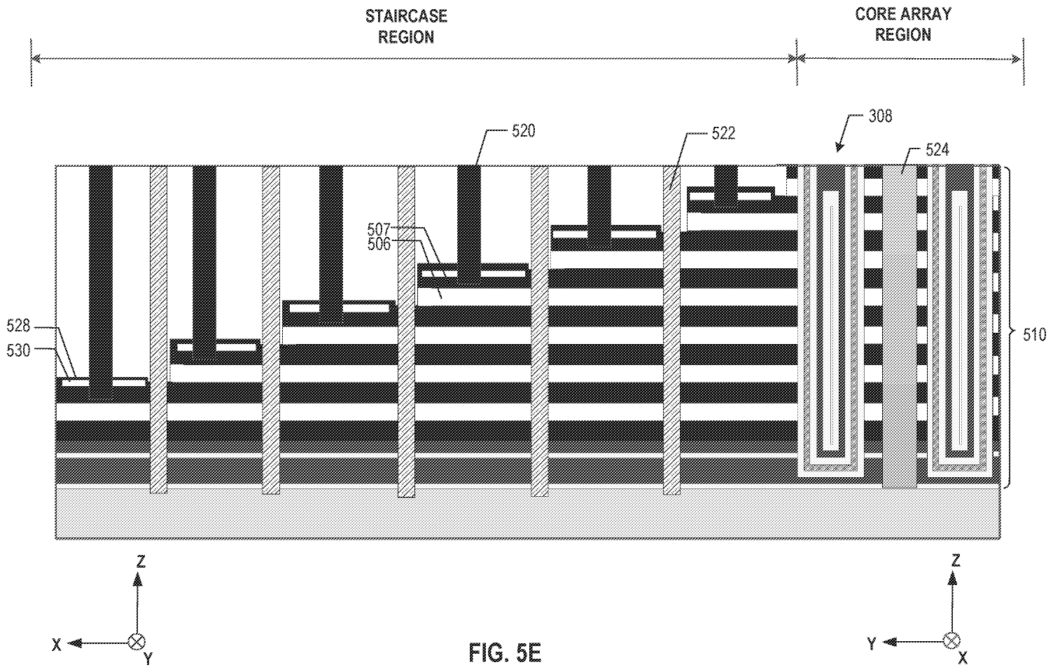

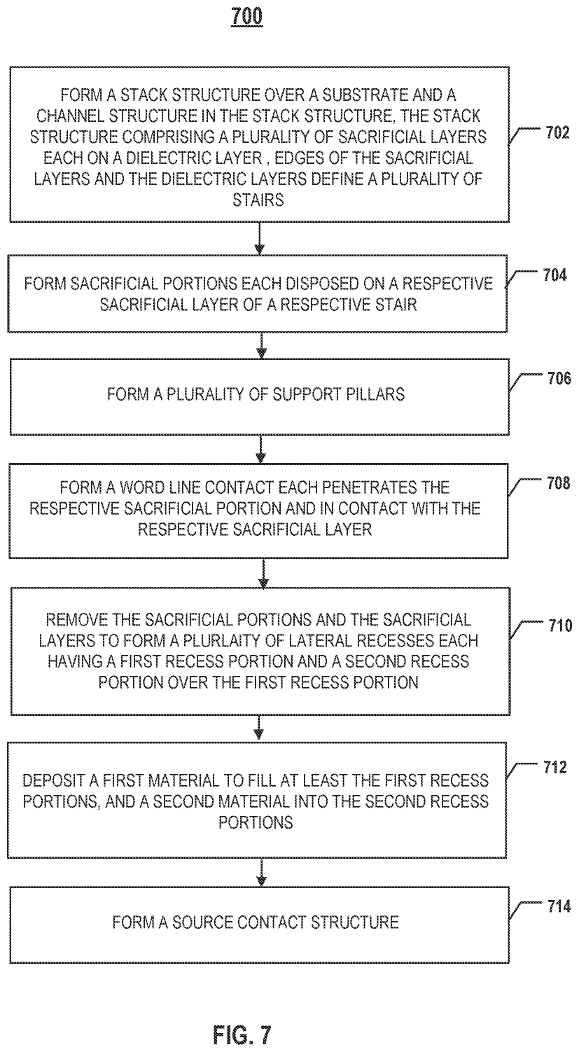

FIGS. 5A-5E illustrate a fabrication process of another 3D memory device, according to some aspects of the present disclosure. The 3D memory device may be an example of 3D memory device 203. FIG. 7 illustrates a flowchart of an exemplary method 700 for forming the 3D memory device, according to some aspects of the present disclosure. For the purpose of better describing the present disclosure, the structures in FIG. 2E and method 700 in FIG. 7 will be discussed together. It is understood that the operations shown in method 700 are not exhaustive and that other operations may be performed as well before, after, or between any of the illustrated operations. Further, some of the operations may be performed simultaneously, or in a different order than shown in FIG. 2E and FIG. 7.

As shown in FIG. 7, method 700 starts at operation 702, in which a stack structure is formed over a substrate, and a channel structure is formed in the stack structure. The stack structure includes a plurality of sacrificial layers each on a dielectric layer. Edges of the dielectric layers and the sacrificial layers define a plurality of stairs. FIGS. 3A and 5A illustrate a corresponding structure.

Referring back to FIG. 3A, material stack structure 309 can be formed on substrate 302. Material stack structure 309 can include interleaved sacrificial material layers 303 and dielectric material layers 305 extending in the x-y plane. A plurality of sacrificial material/dielectric material layer pairs can be formed. In some implementations, each dielectric material layer 305 may include a layer of silicon oxide, and each sacrificial material layer 303 may include a layer of silicon nitride. A plurality of channel structures 308 may be formed extending vertically through material stack structure 309 in the z-direction in the core array region. The materials and fabrication to form material stack structure 309 and channel structures 308 may be referred to the description of FIG. 3A, and the detailed description is not repeated herein.

As shown in FIG. 5A, material stack structure 309 can be patterned to form a stack structure 510, which includes a dielectric stack having a plurality of interleaved sacrificial layers 504 and dielectric layers 506, forming a plurality of sacrificial/dielectric layer pairs. Edges of sacrificial/dielectric layer pairs may define a plurality of stairs. For each stair, a sacrificial layer 504 is over and above a respective dielectric layer 506. The landing area of each stair may be defined as the area of the stair between the vertical surfaces of adjacent stairs. The dielectric stack (e.g., the stairs) may be formed by repeatedly trimming material stack structure 309 vertically and horizontally such that sacrificial layers 504 are exposed. The trimming of the dielectric material stack may include photolithography and etching (e.g., dry and/or wet etching) processes. In some implementations, for each stair, dielectric layer 306 is above and in contact with sacrificial layer 304. As an example, stack structure 510 may be formed by etching stack structure 310 until sacrificial layer 304 of each stair is exposed.

Referring back to FIG. 7, method 700 proceeds to operation 704, in which a plurality of sacrificial portions are formed, each disposed on a respective stair. FIGS. 5B and 5C illustrate corresponding structures.

As shown in FIG. 5B, a layer 514 of a sacrificial material may be deposited over the stairs. Layer 514 may cover at least the landing area of each stair. Layer 514 may be in contact with cover sacrificial layers 504 and have the same material as that of sacrificial layers 504, such as silicon nitride. In some implementations, In some implementations, a total thickness of layer 514 and sacrificial layer 504 is equal to or greater than 55 nm. The sacrificial material of layer 514 may also include other suitable materials such that the sacrificial material of layer 514 and sacrificial layers 504 may be removed in the same etching process in the subsequent gate-replacement process. The deposition of layer 514 may include any suitable thin-film deposition processes such as CVD, PVD, ALD, or any combination thereof.

As shown in FIG. 5C, layer 314 may be patterned to form a plurality of sacrificial portions 516 each disposed on a respective stair. Sacrificial portion 516 may be disposed at the landing area of the respective stair, and in contact with the respective sacrificial layer 504. To form sacrificial portions 516, layer 514 may be patterned to remove portions of the sacrificial material deposited on the side surfaces of the stairs. Each sacrificial portion 516 may thus be disconnected from one another. The patterning of layer 514 may include photolithography and an etching process (e.g., dry and/or wet etching). A dielectric structure 518 may be formed covering the stairs and sacrificial portions 516. The material and fabrication of dielectric structure 518 may be referred to the description of dielectric structure 318, and the detailed description is not repeated herein.

Referring back to FIG. 7, method 700 proceeds to operation 706, in which a plurality of support structures are formed. FIG. 5D illustrates a corresponding structure.

As shown in FIG. 5D, a plurality of support structures 522 may be formed. Support structures 522, e.g., support pillars, may extend vertically in stack structure 510. Support structure 522 may be located in the staircase region and/or the core array region. In the staircase region, support structure 522 may extend in stack structure 510 and dielectric structure 318, e.g., in the staircase region. Support structures 522 may include a dielectric structure such as silicon oxide. The material and fabrication of support structures 522 may be referred to the description of support structure 322, and the detailed description is not repeated herein.

Referring back to FIG. 7, method 700 proceeds to operation 708, in which a word line contact is formed each penetrates a respective sacrificial portion and in contact with a respective sacrificial layer. FIG. 5D illustrates a corresponding structure.

As shown in FIG. 5D, a plurality of word line contacts 520 are formed in contact with sacrificial layer 504 of each stair, penetrating the respective sacrificial portion 516. To form word line contacts 520, a plurality of openings can be formed in dielectric structure 518. The openings may extend vertically in dielectric structure 518 and each in contact with a respective sacrificial portion 516. The openings may be further etched to penetrate the respective sacrificial portion 516 and be in contact with the respective sacrificial layer 504. The conductive material, forming word line contacts 520, are deposited to be in contact with the respective sacrificial layer 504. Word line contacts 520, each penetrating the respective sacrificial portion 516 and in contact with the sacrificial layer 504 of the respective stair, can be formed. The material and fabrication of word line contacts 520 may be referred to the description of word line contacts 320, and the detailed description is not repeated herein. In various implementations, word line contacts 520 are formed prior to the formation of support pillars, referring back to the description of FIGS. 3F-3H. The detailed description of the operations is not repeated herein.

Referring back to FIG. 7, method 700 proceeds to operation 710, in which the sacrificial layers and the sacrificial portions are removed to form a plurality of lateral recesses.

Sacrificial layers 504 and sacrificial portions 516 are removed from stack structure 510. A plurality of lateral recesses, extending laterally in the x-y plane, may be formed from the removal of sacrificial layers 504 and sacrificial portions 516. To form the lateral recesses, one or more slit structures (e.g., gate line slits) may be formed extending through stack structure 510 in the x-z plane, referring back to FIG. 2E. The slit structures may each extend laterally in the x-direction. The slit structures may each be in contact or extend into the top portion of substrate 302. In some implementations, the fabrication process for forming the slit structures may include wet etching and/or dry etching, such as deep reactive ion etching (DRIE). An isotropic etching process, such as wet etching, may be performed through the slit structures to remove sacrificial layers 504 and sacrificial portions 516.

The lateral recesses may each include a first recess portion and a second recess portion over and the first recess portion. The first recess portion may be formed from the removal of a respective sacrificial layer 304. In the x-direction, the length of a first recess portion is greater than that of second recess portion. In some implementations, the first recess portion extends laterally to the edge of the respective stair and also intersects with channel structures 308 in stack structure 510. The second recess portion may be formed by the removal of a respective sacrificial portion 516, and is disposed in the landing area of a respective stair. The first recess portion and the second recess portion are in contact with each other (e.g., connected).

Referring back to FIG. 7, method 700 proceeds to operation 712, in which a first material is deposited into each of the lateral recesses to fill at least the first recess portions. A second material is deposited into the second recess portions. FIG. 5E illustrates a corresponding structure.

As shown in FIG. 5E, a first material may be deposited through the slit structures into the lateral recesses. The first material may fill at least the first recess portions, forming a plurality of conductive layers 507. Depending on the thickness of the second recess portions (or sacrificial portions 516), the second recess portions may or may not be filled by the first material. For example, the second recess portions may be partially filled (e.g., if sacrificial portions 516 are sufficiently thick) or fully filled (e.g., if sacrificial portions 516 are sufficiently thin). In some implementations, when a total thickness of sacrificial layer 504 and the respective sacrificial portion 516 (e.g., sacrificial portion 516 in contact with the sacrificial layer 504) is less than or equal to 55 nm, the first material also fully fills the second recess portions. The first material may include a conductive material, such as tungsten, and can be formed by any suitable thin-film deposition processes such as CVD, PVD, ALD, electroplating, electroless plating, or any combination thereof. In some implementations, a high-k dielectric material is deposited into the lateral recesses as gate dielectric layers. In various implementations, the thickness of sacrificial portion 516 can be in any other suitable range to form 3D memory device 203.

In some implementations, a second material, different from the first material, may be deposited to fill the second recess portions. In some implementations, when a total thickness of sacrificial layer 504 and the respective sacrificial portion 516 (e.g., sacrificial portion 516 in contact with the sacrificial layer 504) is greater than or equal to 55 nm, the first material partially fills the second recess portions. In some implementations, after the deposition of the first material, a recess etching process may be performed, e.g., to remove excess first material deposited on the side surfaces of the slit structures. The recess etch may also partially or fully remove the first material in the second recess portions. The second material may be deposited after the recess etch.

In some implementations, the first material may be partially removed from a second recess portion, and may be retained on at least the upper surface of the second recess portion. For example, a layer 528, formed by any remaining first material on the upper surface of the second portion, can be formed. A layer 530 of the second material is disposed above and in contact, e.g., on, with the respective conductive layer 507 (and layer 528, if any), as shown in FIGS. 5E and 3D memory device 203 in FIG. 2E. The two layers of the first material, layer 528 and conductive layer 507, may or may not be in contact with each other, e.g., on the vertical surfaces of the respective second recess portion. In some implementations, the two layers of the first material are separated by layer 530. In some implementations, the two layers of the first material are in contact with each other on the vertical surfaces on the respective second recess portion. In some implementations, the first material may be fully removed from a second recess portion, and the second recess portion is filled with a single layer of the second material. Layer 530 may include silicon oxide, silicon nitride, silicon oxynitride, polysilicon, carbon, airgap, or any combination thereof. In some implementations, the second material includes silicon oxide. The deposition of the second material may include any suitable thin-film deposition processes such as CVD, PVD, ALD, or any combination thereof. In some implementations, when the second material includes (e.g., or is) airgap, the airgap can be formed by not filling or partially filling the second recess portion.

Referring back to FIG. 7, method 700 proceeds to operation 714, in which a source contact structure is formed in the slit structure. FIG. 5E illustrates a corresponding structure.

As shown in FIG. 5E, a source contact structure 524 is formed in a slit structure. Optionally, one or more recess etching processes may be performed to remove excess materials deposited on the sidewall of the slit structure. The recess etching may include a dry and/or a wet etching process. The material and fabrication of source contact structure 524 may be referred to the description of source contact structure 324, and the detailed description is not repeated herein.

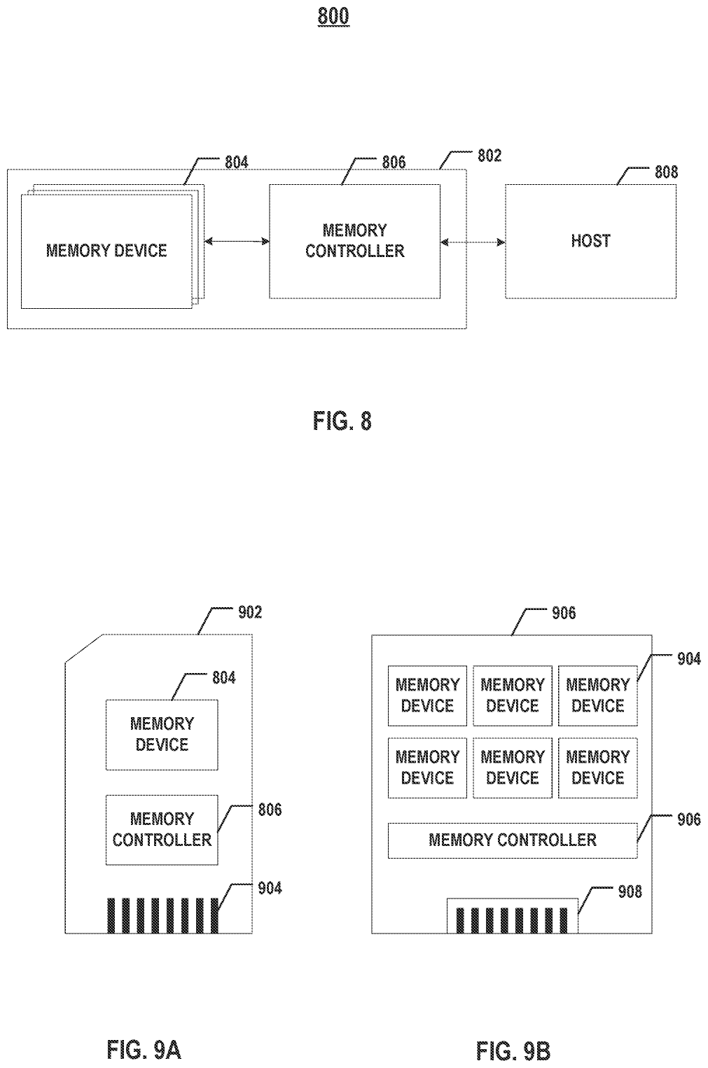

FIG. 8 illustrates a block diagram of an exemplary system 800 having a memory device, according to some aspects of the present disclosure. System 800 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 8, system 800 can include a host 808 and a memory system 802 having one or more memory devices 804 and a memory controller 806. Host 808 can be a processor of an electronic device, such as a central processing unit (CPU), or a system-on-chip (SoC), such as an application processor (AP). Host 808 can be configured to send or receive data to or from memory devices 804.

Memory device 804 can be any memory device disclosed in the present disclosure. As disclosed above in detail, memory device 804, such as a NAND Flash memory device, may have a landing structure on a respective conductive layer. The landing structure has a top layer, made of a conductive material, which is desirably thin to be removed in a recess etching process and desirably thick to provide high electrical conductivity. Memory controller 806 is coupled to memory device 804 and host 808 and is configured to control memory device 804, according to some implementations. Memory controller 806 can manage the data stored in memory device 804 and communicate with host 808. For example, memory controller 806 may be coupled to memory device 804, such as any one of 3D memory devices 200-203 described above, and memory controller 806 may be configured to control operations of the channel structures in any one of 3D memory devices 200-203 such as the application of word line voltages on the landing structures and the conductive materials.

In some implementations, memory controller 806 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 806 is designed for operating in a high duty-cycle environment SSDs or embedded multi-media-cards (eMMCs) used as data storage for mobile devices, such as smartphones, tablets, laptop computers, etc., and enterprise storage arrays. Memory controller 806 can be configured to control operations of memory device 804, such as read, erase, and program operations. Memory controller 806 can also be configured to manage various functions with respect to the data stored or to be stored in memory device 804 including, but not limited to bad-block management, garbage collection, logical-to-physical address conversion, wear leveling, etc. In some implementations, memory controller 806 is further configured to process error correction codes (ECCs) with respect to the data read from or written to memory device 804. Any other suitable functions may be performed by memory controller 806 as well, for example, formatting memory device 804. Memory controller 806 can communicate with an external device (e.g., host 808) according to a particular communication protocol. For example, memory controller 806 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 806 and one or more memory devices 804 can be integrated into various types of storage devices, for example, be included in the same package, such as a universal Flash storage (UFS) package or an eMMC package. That is, memory system 802 can be implemented and packaged into different types of end electronic products. In one example as shown in FIG. 9A, memory controller 806 and a single memory device 804 may be integrated into a memory card 902. Memory card 902 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 902 can further include a memory card connector 904 coupling memory card 902 with a host (e.g., host 808 in FIG. 8). In another example as shown in FIG. 9B, memory controller 806 and multiple memory devices 804 may be integrated into an SSD 906. SSD 906 can further include an SSD connector 908 coupling SSD 906 with a host (e.g., host 808 in FIG. 8). In some implementations, the storage capacity and/or the operation speed of SSD 906 is greater than those of memory card 902.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A three-dimensional (3D) memory device, comprising:
interleaved conductive layers and dielectric layers, wherein edges of the conductive layers and dielectric layers define a plurality of stairs; and
a plurality of landing structures each over a respective conductive layer at a respective stair, wherein each of the landing structures comprises a first layer having a first material and a second layer having a second material, the first layer being over the second layer.

2. The 3D memory device of claim 1, wherein the second layer is between the first layer and the respective conductive layer.

3. The 3D memory device of claim 1, wherein the first material comprises a conductive material and the second material comprises a dielectric material.

4. The 3D memory device of claim 1, wherein the first material comprises tungsten.

5. The 3D memory device of claim 1, wherein the second material comprises silicon oxide, silicon oxynitride, or a combination thereof.

6. The 3D memory device of claim 1, wherein at each of the plurality of stairs, a respective dielectric layer is above and in contact with a respective conductive layer.

7. The 3D memory device of claim 3, comprising a cover dielectric layer, the cover dielectric layer comprising a plurality of portions over the plurality of stairs, wherein, at the each of the plurality of stairs,
a respective portion of the cover dielectric layer is in contact with the respective dielectric layer and the respective conductive layer; and
the second layer comprises the portion of the cover dielectric layer and a portion of the respective dielectric layer.

8. The 3D memory device of claim 6, wherein the first material comprises tungsten, and the second material comprises silicon oxide.

9. The 3D memory device of claim 8, wherein a thickness of the first layer is less than or equal to 55 nm.

10. The 3D memory device of claim 6, wherein the landing structure further comprises a third layer having a third material, the third layer in the first layer and being different from the first material.

11. The 3D memory device of claim 10, wherein the third material is fully surrounded by the first layer.

12. The 3D memory device of claim 10, wherein the third material comprises silicon oxide, silicon nitride, airgap, silicon oxynitride, polysilicon, carbon, or a combination thereof.

13. A memory system, comprising:
a three-dimensional (3D) memory device, comprising:
interleaved conductive layers and dielectric layers, wherein edges of the conductive layers and dielectric layers define a plurality of stairs; and
a plurality of landing structures each over a respective conductive layer at a respective stair, wherein each of the landing structures comprises a first layer having a first material and a second layer having a second material, the first layer being over the second layer, and
a memory controller coupled to the 3D memory device and configured to control operations of the 3D memory device.

14. The memory system of claim 13, wherein the second layer is between the first layer and the respective conductive layer.

15. A method for forming a three-dimensional (3D) memory device, comprising:
forming a stack structure comprising interleaved sacrificial layers and dielectric layers, edges of the dielectric layers and the sacrificial layers defining a plurality of stairs;
forming sacrificial portions each on a respective stair;
forming a plurality of interconnect structures each penetrating the respective sacrificial portion and in contact with a respective sacrificial layer of the respective stair;
removing the sacrificial portions and the sacrificial layers to form a plurality of lateral recesses; and
depositing a conductive material into the lateral recesses.

16. The method of claim 15, wherein:
the lateral recesses each comprising a first recess portion and a second recess portion over the first recess portion; and
depositing the conductive material into the lateral recesses comprises filling the first recess portion and filling at least part of the second recess portion of each of the lateral recesses.

17. The method of claim 16, wherein depositing the conductive material comprises fully filling the first recess portion of each of the lateral recesses.

18. The method of claim 16, wherein depositing the conductive material comprises fully filling the second recess portion of each of the lateral recesses.

19. The method of claim 16, wherein depositing the conductive material comprises partially filling the second recess portion of each of the lateral recesses.

20. The method of claim 15, wherein depositing the conductive material comprises depositing tungsten, aluminum, cobalt, copper, polysilicon, or a combination thereof.
